(19) United States
(12) Patent Application Publication
(10) Pub. No.: US 2025/0197985 A1
(43) Pub. Date: Jun. 19, 2025

(54) VAPOR DEPOSITION MASK AND METHOD FOR MANUFACTURING LIGHT-EMITTING ELEMENT

(71) Applicant: CANON KABUSHIKI KAISHA, Tokyo (JP)

(72) Inventors: HIDEKI KODAMA, Kanagawa (JP); JUN YAMAGUCHI, Kanagawa (JP); HIROYUKI MOCHIZUKI, Kanagawa (JP); MASUMI ITABASHI, Kanagawa (JP)

(21) Appl. No.: 18/977,709

(22) Filed: Dec. 11, 2024

(30) Foreign Application Priority Data
Dec. 13, 2023 (JP) 2023-209997

(51) Int. Cl. C23C 14/04; H10K 71/16

(52) U.S. Cl. CPC C23C 14/042; C23C 14/046; H10K 71/166

(57) ABSTRACT

A vapor deposition mask includes a mask substrate including a recessed portion disposed on an opposing surface opposed to a substrate, and a peripheral portion surrounding the recessed portion, and a plurality of projection portions disposed in the mask substrate, wherein a bottom portion of the recessed portion includes a plurality of openings and a beam portion disposed between the plurality of openings, wherein the plurality of projection portions is disposed on an upper surface of the beam portion, and wherein a projection portion is not disposed on the opposing surface of the peripheral portion opposed to the substrate.

### BACKGROUND

### Field

The present disclosure relates to a vapor deposition mask and a method for manufacturing an organic light-emitting element using the vapor deposition mask.

### Description of the Related Art

An organic light-emitting element draws attention as a light-emitting element capable of high-luminance light emission by low-voltage driving. The organic light-emitting element is generally formed of a laminated structure of a plurality of layers such as an anode, a hole transport layer, a light-emitting layer, an electron transport layer, and a cathode on a substrate. Examples of a method for forming this laminated structure include a vacuum vapor deposition method for performing vacuum vapor deposition on a substrate using evaporation and sublimation, and a film formation method for dissolving an organic material into a solvent and using inkjet or spin coating.

Among these methods, in the formation of a laminated structure using a low-molecular material, a vacuum vapor deposition method using a mask in which a pattern is disposed is generally used. In the vacuum vapor deposition method, to form a film of a desired pattern on a substrate, a vapor deposition mask having a pattern of desired pixel opening portions is installed between the substrate and a heated portion of a vapor deposition material, and the film is formed.

The vacuum vapor deposition method needs to bring the substrate and the vapor deposition mask close to each other, thereby reducing vapor deposition blur and vapor deposition vignetting when vapor deposition is performed. The “vapor deposition blur” refers to the formation of a film of the vapor deposition material in a wide range beyond a desired vapor deposition range. The distance between the substrate and the vapor deposition mask is important for this. Even if the substrate and the vapor deposition mask are installed in an assumed positional relationship when vapor deposition is performed, a crosspiece portion dividing pixel openings may bend by the weight of the vapor deposition mask itself in a center portion of the vapor deposition mask. This causes deposition blur.

In recent years, an increase in the size of an organic light-emitting element has occurred. Accordingly, the size of a vapor deposition mask should also be increased. If the size of the vapor deposition mask is increased, the above bending of the crosspiece portion of the vapor deposition mask by the weight of the vapor deposition mask itself is greater. If the vapor deposition mask bends, a vapor deposition source comes around in vapor deposition, and deposition blur occurs such that a film of the vapor deposition material is also formed at a position other than a desired position on the substrate.

Thus, to achieve increases in the sizes of a substrate and a vapor deposition mask, it is preferable to bring the vapor deposition mask and the substrate into close contact with each other. In a case where a mask made of a magnetic substance is used to this end, a method for installing a magnet on a back surface of a substrate and attracting the mask made of the magnetic substance to the substrate by a magnetic force is discussed. In this method, when a substrate and a vapor deposition mask made of a metal come into contact with each other, a vapor-deposited film and the mask made of the metal may rub against each other, and the vapor-deposited film and the surface of the substrate may be damaged. Thus, in the publication of Japanese Patent Application Laid-Open No. 2007-95411, projection portions made of a resin are provided in the outer periphery of a display unit on the side where a surface of a metal mask is opposed to a substrate when the metal mask is vapor-deposited.

However, when a vapor deposition mask made of a magnetic substance is attracted to a substrate by a magnetic force, the frictional force between a projection made of a resin on the metal mask and the substrate may be small. Thus, the mask may be shifted, and a shift may occur from a desired film formation position of a vapor-deposited film.

### SUMMARY

The present disclosure is directed to providing a technique related to a vapor deposition mask in which a positional shift in film formation is reduced when the vapor deposition mask and a substrate are brought into close contact with each other in vapor deposition.

According to some embodiments, a vapor deposition mask includes a mask substrate including a recessed portion disposed on an opposing surface opposed to a substrate, and a peripheral portion surrounding the recessed portion, and a projection portion disposed in the mask substrate, wherein a bottom portion of the recessed portion includes a first opening and a second opening adjacent to each other in a first direction, a third opening and a fourth opening adjacent to each other in the first direction and adjacent to the first and second openings in a second direction intersecting the first direction, and a beam portion disposed between the first and second openings, between the third and fourth openings, between the first and third openings, between the second and fourth openings, and between the first and fourth openings, wherein the projection portion is disposed on an upper surface of the beam portion, and wherein in a case where in a planar view of the upper surface, a region obtained by combining the first to fourth openings and the beam portion is a first region, and a region having a same area and a same outer shape as an area and an outer shape of the first region in the peripheral portion is a second region, an area of contact of the opposing surface of the second region with a parallel surface parallel to the opposing surface is greater than an area of contact of the opposing surface of the first region with the parallel surface.

According to another aspect of the present disclosure, a vapor deposition mask includes a mask substrate including a recessed portion disposed on an opposing surface opposed to a substrate, and a peripheral portion surrounding the recessed portion, and a plurality of projection portions disposed in the mask substrate, wherein a bottom portion of the recessed portion includes a plurality of openings and a beam portion disposed between the plurality of openings, wherein the plurality of projection portions is disposed on an upper surface of the beam portion, and wherein a projection portion is not disposed on the opposing surface of the peripheral portion opposed to the substrate.

Further features of the present disclosure will become apparent from the following description of exemplary embodiments with reference to the attached drawings.

### BRIEF DESCRIPTION OF THE DRAWINGS

FIG. 1A is a schematic cross-sectional view for describing a vapor deposition mask according to an exemplary embodiment, FIG. 1B is a schematic plan view of the vapor deposition mask in FIG. 1A, and FIG. 1C is an enlarged view of a portion surrounded by a dashed-dotted line in FIG. 1A.

FIGS. 2A and 2B are schematic cross-sectional views for describing a positional shift when vapor deposition is performed.

FIG. 3A is a schematic cross-sectional view for describing a vapor deposition mask according to an exemplary embodiment, and FIG. 3B is a schematic plan view of the vapor deposition mask in FIG. 3A.

FIG. 4A is a schematic cross-sectional view for describing a vapor deposition mask according to an exemplary embodiment, and FIG. 4B is a schematic plan view of the vapor deposition mask in FIG. 4A.

FIGS. 5A, 5B, 5C, and 5D are diagrams for describing a part of a manufacturing process for manufacturing a light-emitting element using a vapor deposition mask according to an exemplary embodiment.

FIG. 6A is a schematic cross-sectional view illustrating an example of a pixel of a display apparatus according to an exemplary embodiment, and FIG. 6B is a schematic cross-sectional view illustrating an example of a display apparatus using an organic light-emitting element according to an exemplary embodiment.

FIG. 7 is a schematic diagram illustrating an example of a display apparatus including an organic light-emitting element according to an exemplary embodiment.

FIG. 8A is a schematic diagram illustrating an example of an imaging apparatus according to an exemplary embodiment, and FIG. 8B is a schematic diagram illustrating an example of an electronic device according to an exemplary embodiment.

FIG. 9A is a schematic diagram illustrating an example of a display apparatus according to an exemplary embodiment, and FIG. 9B is a schematic diagram illustrating an example of a foldable display apparatus.

FIG. 10A is a schematic diagram illustrating an example of an illumination apparatus according to an exemplary embodiment.

FIG. 10B is a schematic diagram illustrating an example of an automobile including a lamp fitting for a vehicle according to an exemplary embodiment.

FIG. 11A is a schematic diagram illustrating an example of a wearable device according to an exemplary embodiment, and FIG. 11B is a schematic diagram illustrating an example of a wearable device according to an exemplary embodiment and a form in which the wearable device includes an imaging apparatus.

FIG. 12A is a schematic view illustrating an image forming apparatus according to an exemplary embodiment, and FIGS. 12B and 12C are schematic views illustrating forms in which a plurality of light-emitting units of an exposure light source is placed on a long substrate.

FIGS. 13A and 13B are diagrams for describing vapor deposition masks according to comparative examples.

FIGS. 14A and 14B are diagrams for describing an evaluation of a positional shift in film formation when vapor deposition is performed.

### DESCRIPTION OF THE EMBODIMENTS

Various exemplary embodiments, features, and aspects of the present disclosure will be described with reference to the drawings. The present disclosure is not limited to the exemplary embodiments, and can be modified and changed as appropriate without departing from the spirit of the present disclosure.

In the drawings used for the following description, there is a case where components having the same or similar functions or configurations are designated by the same sign, and the description of the components is omitted or simplified.

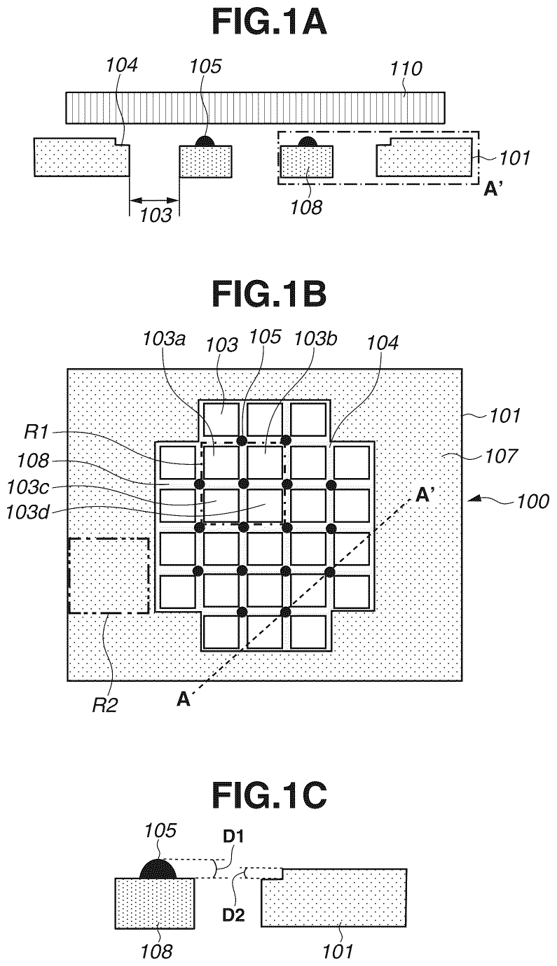

With reference to FIGS. 1A, 1B, and 1C, an example of a vapor deposition mask according to a first exemplary embodiment is described. The vapor deposition mask according to the present exemplary embodiment can be used to form a desired pattern on a substrate by a vacuum vapor deposition method, for example.

The vapor deposition mask may be a mask made of a magnetic metal, or may be a mask using a nonmagnetic material such as a resin or silicon. Further, the vapor deposition mask may be formed of each of these materials alone, or may be formed by combining a plurality of these materials. In terms of wet etching processing and electroforming processing, a part of the mask is formed using a resin or silicon, whereby it is also possible to form the mask to be thinner by higher-accuracy processing than in a case where the mask is formed using a metal.

With reference to FIGS. 1A to 1C, an example of a vapor deposition mask 100 according to the present exemplary embodiment is described. FIG. 1A is a cross-sectional view (a schematic cross-sectional view) illustrating the vapor deposition mask 100 and a substrate 110 and a vapor deposition pattern. FIG. 1B is a plan view (a schematic plan view) of the vapor deposition mask 100 illustrated in FIG. 1A when a surface of the vapor deposition mask 100 opposed to the substrate 110 is planarly viewed. More specifically, a part of the vapor deposition mask 100 illustrated in FIG. 1A is a cross-sectional view of a portion of the vapor deposition mask 100 in FIG. 1B along a cross section A-A′. FIG. 1C is an enlarged view of a portion surrounded by a dashed-dotted line in FIG. 1A.

The vapor deposition mask 100 according to the present exemplary embodiment includes a mask substrate 101 including a recessed portion 104 disposed on a surface (an opposing surface) opposed to a substrate 110 on which a vapor deposition pattern 111 is formed, and a peripheral portion 107 surrounding the recessed portion 104. The vapor deposition mask 100 also includes projection portions 105 disposed in the mask substrate 101.

A bottom portion of the recessed portion 104 includes a plurality of openings 103 and a beam portion 108 disposed between the plurality of openings 103. The projection portions 105 are disposed on an upper surface of the beam portion 108. FIG. 1A illustrates an example where a plurality of projection portions 105 is disposed on the upper surface of the beam portion 108 in the recessed portion 104.

The recessed portion 104 is opposed to an effective region (a region where an organic light-emitting element is formed) of the substrate 110. On the other hand, the peripheral portion 107 is used to fix the vapor deposition mask 100 and the substrate 110, and an effective element such as the organic light-emitting element is not disposed in a region of the substrate 110 opposed to the peripheral portion 107.

In the configuration of the vapor deposition mask 100 according to the present exemplary embodiment, when the substrate 110 and the vapor deposition mask 100 come into contact with each other, the surface of the peripheral portion 107 opposed to the substrate 100 and the ends of the projection portions 105 come into contact with the substrate 110. Since the ends of the projection portions 105 come into contact with the effective region of the substrate 110, the vapor deposition mask 100 can come into contact with the substrate 110 by avoiding an element such as the organic light-emitting element disposed in the effective region. On the other hand, the projection portions 105 are not disposed on the surface of the peripheral portion 107 opposed to the substrate 110. Thus, the peripheral portion 107 comes into contact with the substrate 110 in the entirety of the opposing surface opposed to the substrate 110.

That is, in the vapor deposition mask 100, a proportion of an area of contact of the substrate 110 and the vapor deposition mask 100 to a region having a certain area in the peripheral portion 107 is larger than a proportion of an area of contact of the substrate 110 and the vapor deposition mask 100 to a region having the same area as the certain area in the recessed portion 104 . . . . Consequently, the frictional force of the opposing surface opposed to the substrate 110 in a region having a certain area in the peripheral portion 107 against a surface (a parallel surface) parallel to the opposing surface is greater than the frictional force of the opposing surface in a region having the same area and the same shape (outer shape) as those of the above region in the recessed portion 104 against the parallel surface.

It is possible to increase the area (the proportion) of contact of the vapor deposition mask 100 and the substrate 110 when the substrate 110 and the vapor deposition mask 100 are brought into contact with each other, compared to a case where the projection portions 105 are disposed in the entirety of the opposing surface of the vapor deposition mask 100 opposed to the substrate 110. Consequently, it is possible to reduce a positional shift between the vapor deposition mask 100 and the substrate 110 that occurs by the vapor deposition mask 100 or the substrate 110 sliding. Thus, it is possible to reduce a shift in the film formation position of the vapor deposition pattern 111 due to a positional shift between the vapor deposition mask 100 and the substrate 110.

With reference to FIG. 1B, the vapor deposition mask 100 according to the present exemplary embodiment is described in more detail.

The bottom portion of the recessed portion 104 of the vapor deposition mask 100 includes the plurality of openings 103 and the beam portion 108 disposed between the plurality of openings 103. An example is illustrated where the beam portion 108 has a grid shape in the recessed portion 104 in the planar view of the opposing surface of the vapor deposition mask 100 opposed to the substrate 110.

The plurality of projection portions 105 is disposed at the intersections of the lines of the grid. The vapor deposition pattern 111 is formed by vapor-depositing a vapor deposition material on the substrate 110 through the openings 103 of the vapor deposition mask 100. Thus, in a case where the projection portions 105 are disposed in the beam portion 108, it is desirable that the placement positions of the projection portions 105 have a margin. The projection portions 105 are disposed at the intersections of the lines of the grid of the beam portion 108, whereby it is possible to leave a margin for the placement of the projection portions 105 than in a case where the projection portions 105 are disposed in portions of the sides of the grid shape. Thus, it is possible to prevent a decrease in the accuracy of the shape of the vapor deposition pattern 111 because the projection portions 105 overlap parts of the openings 103 due to a shift in the placement of the projection portions 105.

In the recessed portion 104, a region formed by connecting the outer shapes of a first opening 103a, a second opening 103b, a third opening 103c, a fourth opening 103d, and portions of the beam portion 108 disposed between these openings is a first region R1. In FIG. 1B, the region R1 is a region surrounded by a dotted line. In the peripheral portion 107, a region having the same area and the same outer shape as those of the region R1 is a second region R2.

The first opening 103a and the second opening 103b are adjacent to each other in a first direction, and the third opening 103c and the fourth opening 103d are adjacent to each other in the first direction. The first opening 103a and the third opening 103c are adjacent to each other in a second direction intersecting the first direction, and the second opening 103b and the fourth opening 103d are adjacent to each other in the second direction. Although FIG. 1B illustrates an example where the first and second directions are orthogonal to each other, the relationship between the first and second directions is not limited to this. The first and second directions may intersect each other at an angle less than 90 degrees. In the specification, the grid shape includes not only a case where the lines of the grid intersect each other at a right angle, but also a case where the lines of the grid intersect each other at an angle less than 90 degrees.

In the vapor deposition mask 100 according to the present exemplary embodiment, the area of contact of the opposing surface of the second region R2 opposed to the substrate 110 with the parallel surface parallel to the opposing surface is greater than the area of contact of the opposing surface of the first region R1 with the parallel surface. Thus, the frictional force of the opposing surface of the second region R2 against the parallel surface is greater than the frictional force of the opposing surface of the first region R1 against the parallel surface. That is, it is possible to make the frictional force between the vapor deposition mask 100 and the substrate 110 greater than in a configuration in which the projection portions 105 are disposed similarly to the recessed portion 104 also in the peripheral portion 107. Thus, when the vapor deposition mask 100 and the substrate 110 are brought into contact with each other, it is possible to reduce the situation where a positional shift occurs between the vapor deposition mask 100 and the substrate 110 by the vapor deposition mask 100 or the substrate 110 sliding and a positional shift occurs in a film formation pattern.

The ends of the projection portions 105 and a portion of the peripheral portion 107 including the opposing surface opposed to the substrate 110 may have different materials. For example, in a case where the mask substrate 101 has a metal, the ends of the projection portions 105 may have a resin. In this case, in the vapor deposition mask 100 in FIG. 1A, the ends of the projection portions 105 have the resin, and the portion of the peripheral portion 107 including the opposing surface has the metal.

With this configuration, it is possible to make the ends of the projection portions 105 that abut the effective region of the substrate 110 where an effective element is formed softer than the portion of the peripheral portion 107 that comes into contact with the substrate 110. Thus, it is possible to reduce the breakage of an element disposed in the effective region or the deterioration of an element due to the occurrence of a crack in the substrate 110.

A configuration may be employed in which bottom portions of the projection portions 105 are formed of parts of the mask substrate 101 and the ends of the projection portions 105 have the resin. Alternatively, a configuration may be employed in which the projection portions 105 having the resin are disposed on the beam portion 108. As the resin, for example, any one or more of a polyimide resin, an acrylic resin, and an epoxy resin can be used. In this case, the projection portions 105 have a polyimide resin. For example, the projection portions 105 can be formed by applying the resin with a dispenser.

As the metal, for example, an invar material can be used. In a case where the substrate 110 and the vapor deposition mask 100 are brought into close contact with each other using a magnetic force, iron or stainless steel having strong magnetism may be used.

FIG. 1C is an enlarged view of a portion of the vapor deposition mask 100 in FIG. 1A surrounded by a dashed-dotted line and is a schematic cross-sectional view of a part of the vapor deposition mask 100 in a cross section passing through a projection portion 105 and the beam portion 108. In FIG. 1C, the distance from an upper surface of the recessed portion 104 to an upper surface of the projection portion 105 in a direction perpendicular to the opposing surface of the vapor deposition mask 100 opposed to the substrate 110 is a distance D1, and the distance from the upper surface of the recessed portion 104 to an upper surface (the opposing surface) of the peripheral portion 107 in the direction perpendicular to the opposing surface is a distance D2. At this time, the distance D1 is greater than or equal to the distance D2. With this configuration, it is possible to suitably bring the vapor deposition mask 100 and the substrate 110 into contact with each other.

If the distance D1 from the upper surface of the recessed portion 104 to the end of the projection portion 105 is smaller than the distance D2 from the upper surface of the recessed portion 104 to the upper surface of the peripheral portion 107, the projection portion 105 may not abut the substrate 110. In this case, a space occurs between the vapor deposition mask 100 and the effective region of the substrate 110, deposition blur occurs, and a positional shift in the film formation pattern relative to a desired film formation position occurs. On the other hand, the distance D1 is set to be greater than or equal to the distance D2, whereby it is possible to bring the projection portion 105 and the substrate 110 into contact with each other and reduce deposition blur.

Further, it is desirable that the distance D1 from the upper surface of the recessed portion 104 to the end of the projection portion 105 be greater than the distance D2 from the upper surface of the recessed portion 104 to the upper surface of the peripheral portion 107. In the present exemplary embodiment, it is desirable that the end of the projection portion 105 have elasticity higher than (hardness smaller than) that of the portion of the peripheral portion 107 including the opposing surface and formed of a resin or a metal. Thus, even if the distance D1 is made greater than the distance D2 and the projection portion 105 abuts the substrate 110 before the peripheral portion 107 does, a great force to destroy an element on the substrate 110 is not applied. On the other hand, it is possible to securely bring the vapor deposition mask 100 and the substrate 110 into close contact with each other. Thus, it is possible to suitably reduce deposition blur and a positional shift in the film formation pattern.

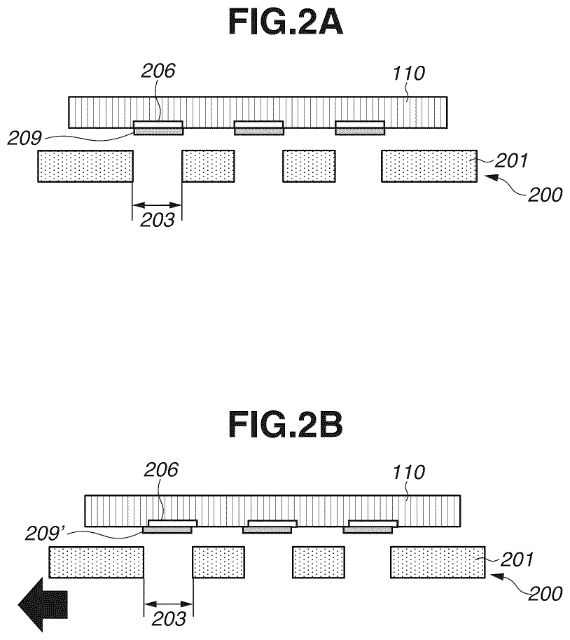

Next, with reference to FIGS. 2A and 2B, a film formation positional shift (a positional shift) that occurs in a vapor deposition mask is described. FIGS. 2A and 2B illustrate schematic cross-sectional views of a vapor deposition mask 200, the substrate 110, and a film formation pattern 209 when vapor deposition is performed. It is desirable that, on the substrate 110, a film of the film formation pattern 209 be formed in contact with desired positions 206 on the substrate 110 by a vapor deposition material evaporated from an evaporation source being vapor-deposited by a vapor deposition source that has passed through opening portions 203 of the vapor deposition mask 200.

On the other hand, in a case where the vapor deposition mask 200 is shifted relative to the substrate 110 when the substrate 110 and the vapor deposition mask 200 are brought into contact with each other, then as illustrated in FIG. 2B, a film of a film formation pattern 209′ is formed at positions shifted from the desired positions 206. As described above, the state where a film of the film formation pattern 209 to be formed at positions corresponding to the opening portions 203 of the vapor deposition mask 200 is formed at positions shifted from the desired positions 206 on the substrate 110 is referred to as “a positional shift in film formation”.

By using the vapor deposition mask 200 according to the present exemplary embodiment, it is possible to reduce a positional shift in film formation when the film formation pattern 209 is formed by vapor deposition.

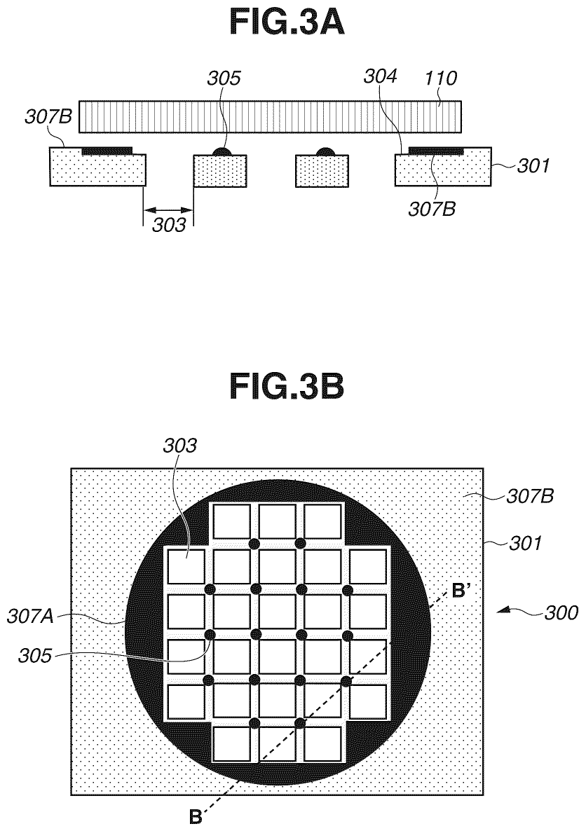

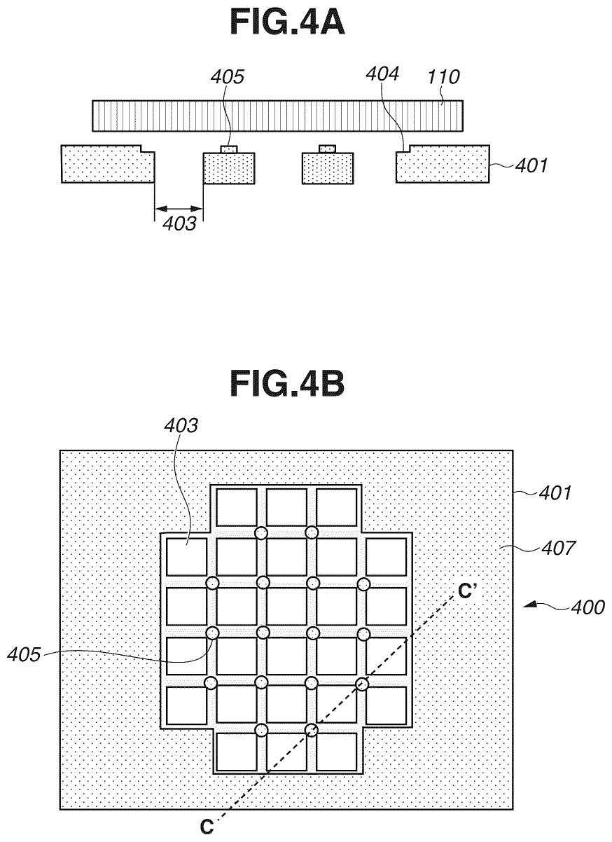

With reference to FIGS. 3A, 3B, 4A, and 4B, other forms of the vapor deposition mask 200 are described. In a second exemplary embodiment, portions different from the first exemplary embodiment are described, and the same configurations, functions, and effects as those in the first exemplary embodiment are not described. Thus, a portion that is designated by a different sign from the first exemplary embodiment but is not described can have a configuration, a function, and an effect similar to those in the first exemplary embodiment.

FIG. 3A is a cross-sectional view (a schematic cross-sectional view) illustrating a vapor deposition mask 300 and the substrate 110.

FIG. 3B is a plan view (a schematic plan view) of the vapor deposition mask 300 illustrated in FIG. 3A when a surface of the vapor deposition mask 300 opposed to the substrate 110 is planarly viewed. More specifically, a part of the vapor deposition mask 300 illustrated in FIG. 3A is a cross-sectional view of a portion of the vapor deposition mask 300 in FIG. 3B along a cross section B-B′.

A peripheral portion 307 of the vapor deposition mask 300 according to the present exemplary embodiment includes an opposing portion 307A including an opposing surface opposed to the substrate 110 and a non-opposing portion 307B that is adjacent to the opposing portion 307A and is not opposed to the substrate 110. In the present exemplary embodiment, projection portions 305 and the opposing portion 307A have the same material. For example, a configuration can be employed in which the projection portions 305 and the opposing portion 307A have a resin. The opposing portion 307B also has the resin, whereby it is possible to prevent a scratch or a crack from occurring also on the periphery of the effective region of the substrate 110 when the substrate 110 and the vapor deposition mask 300 are brought into contact with each other.

Also, in the vapor deposition mask 300 according to the present exemplary embodiment, a ratio of an area of a region in contact with the substrate 110 to an area of a region opposed to the substrate 110 in the peripheral region 307 is larger than a ratio of an area of a region in contact with the effective region of the substrate 110 to an area of a region opposed to the effective region of the substrate. Thus, it is possible to reduce the breakage of an effective element disposed in the effective region and the occurrence of a crack in the substrate 110 and also reduce a positional shift between the substrate 110 and the vapor deposition mask 300.

Although an example has been illustrated where a part of the peripheral portion 307 has the same material as that of the projection portions 305, the vapor deposition mask 300 according to the present exemplary embodiment is not limited to this. For example, a portion of the mask substrate 301 including a front surface of the surface opposed to the substrate 110 may have the same material as that of the projection portions 305.

With reference to FIGS. 4A and 4B, an example of the vapor deposition mask 200 different from FIGS. 3A and 3B is described.

FIG. 4A is a cross-sectional view (a schematic cross-sectional view) illustrating a vapor deposition mask 400 and the substrate 110. FIG. 4B is a plan view (a schematic plan view) of the vapor deposition mask 400 illustrated in FIG. 4A when a surface of the vapor deposition mask 400 opposed to the substrate 110 is planarly viewed. More specifically, a part of the vapor deposition mask 400 illustrated in FIG. 4A is a cross-sectional view of a portion of the vapor deposition mask 400 illustrated in FIG. 4B along a cross section C-C′.

Projection portions 405 of the vapor deposition mask 400 according to the present exemplary embodiment have the same material as that of a peripheral portion 407.

For example, when the peripheral portion 407 is formed, the projection portions 405 can be formed by similarly molding a mask substrate 401. Thus, in the vapor deposition mask 400 according to the present exemplary embodiment, the projection portions 405 and the peripheral portion 407 can have a metal such as invar. In this case, since the step of separately creating the projection portions 405 does not exist, it is possible to reduce the manufacturing cost.

Also, in the vapor deposition mask 400 according to the present exemplary embodiment, a ratio of an area of a region in contact with the substrate 110 to an area of a region opposed to the substrate 110 in the peripheral region 407 is larger than a ratio of an area of a region in contact with the effective region of the substrate 110 to an area of a region opposed to the effective region of the substrate. Thus, it is possible to reduce the breakage of an effective element disposed in the effective region and the occurrence of a crack in the substrate 110 and also reduce a positional shift between the substrate 110 and the vapor deposition mask 400.

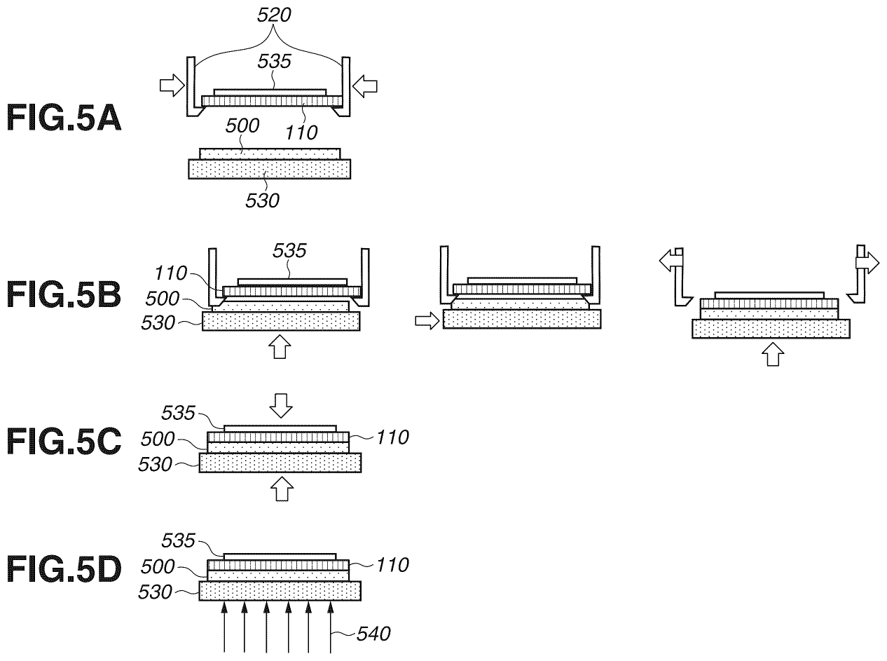

Next, with reference to FIGS. 5A, 5B, 5C, and 5D, a part of the step of forming a light-emitting device is described. The present exemplary embodiment, however, is not limited to this.

In a vapor deposition chamber, for example, with the following configuration, it is possible to form at least any of an electrode of an organic light-emitting element and a plurality of layers included in an organic layer on the substrate 110. A method for manufacturing a part of an organic light-emitting element includes the step of opposing a vapor deposition mask including a plurality of openings and a substrate on which a first electrode and an organic layer are disposed, and the step of adjusting the positions of the substrate and the vapor deposition mask. Further, the method for manufacturing a part of an organic light-emitting element includes the step of bringing the substrate and the vapor deposition mask into contact with each other, and the step of forming a second electrode by vapor-depositing a vapor deposition material on the substrate through the openings of the vapor deposition mask.

First, as illustrated in FIG. 5A, the substrate 110 held by a substrate holding arm 520 and a vapor deposition mask 500 disposed on a mask stage 530 and including a plurality of openings are opposed to each other. On the substrate 110, any of a first electrode, an insulating layer that electrically separates the first electrode, and an organic layer may be formed. Wiring, a pad, or a circuit for driving an organic light-emitting element may also be formed. As the vapor deposition mask 500, any of the vapor deposition masks according to the first and second exemplary embodiments can be used.

Next, as illustrated in FIG. 5B, the positions of the substrate 110 and the vapor deposition mask 500 are adjusted by, for example, moving either one or both of the substrate 110 and the vapor deposition mask 500. Then, as illustrated in FIG. 5C, the substrate 110 and the vapor deposition mask 500 are brought into contact with each other by a magnetic force. At this time, the substrate 110 and the vapor deposition mask 500 are brought into contact with each other by a magnetic force between a magnet 535 disposed on a surface of the substrate 110 on the opposite side of the vapor deposition mask 500 and the mask substrate 101 having a metal. Next, as illustrated in FIG. 5D, a vapor deposition pattern is formed on the substrate 110 by vapor-depositing a vapor deposition material 540 on the substrate 110 through the openings of the vapor deposition mask 500.

In the step of bringing the substrate 110 and the vapor deposition mask 500 into contact with each other, the vapor deposition mask 500 comes into contact with the substrate 110 in projection portions (omitted in FIGS. 5A to 5D) in the effective region of the substrate 110, while the vapor deposition mask 500 comes into contact with the substrate 110 on an upper surface of a peripheral portion in the peripheral portion. Thus, it is possible to reduce the breakage of an effective element disposed in the effective region and the occurrence of a crack in the substrate 110 and also reduce a positional shift between the substrate 110 and the vapor deposition mask 500. Consequently, it is possible to form a film formation pattern in which a positional shift in film formation is reduced.

A manufacturing apparatus for manufacturing an organic light-emitting element in this case is merely an example, and the present exemplary embodiment is not limited to this. A light-emitting element includes a plurality of functional layers, and a vapor deposition apparatus that is a manufacturing apparatus for manufacturing the light-emitting element includes many vapor deposition chambers corresponding to the plurality of functional layers. The vapor deposition apparatus may also include a plurality of processing chambers such as a preparation chamber, a preprocessing chamber, a conveyance chamber, a relay chamber, and a substrate stock chamber in addition to the vapor deposition chambers.

In a fourth exemplary embodiment, a description is given of configuration examples and application examples of an organic light-emitting element formed using each of the vapor deposition masks and the method for manufacturing an organic light-emitting element according to the above exemplary embodiments.

### [Configuration of Organic Light-Emitting Element]

Next, an organic light-emitting element manufactured using the vapor deposition mask 100 in the present exemplary embodiment is described. In the present exemplary embodiment, an organic light-emitting element is provided by forming an insulating layer, a first electrode, an organic compound layer, and a second electrode on a substrate. On a cathode, a protection layer, a color filter, and a microlens may be provided. In a case where the color filter is provided, a planarization layer may be provided between the color filter and the protection layer. The planarization layer can be composed of an acrylic resin. The same applies to a case where a planarization layer is provided between the color filter and the microlens.

### [Substrate]

Examples of the material of the substrate included in the organic light-emitting element include at least one of materials such as quartz, glass, silicon, a resin, and a metal. On the substrate, a switching element such as a transistor and wiring may be provided. On the switching element and the wiring, the insulating layer may be provided. The material of the insulating layer does not matter so long as a contact hole can be formed so that wiring can be formed between the insulating layer and the first electrode, and insulation with wiring to which the insulating layer is not connected can be ensured. For example, a polyimide resin, silicon oxide, or silicon nitride can be used.

### [Electrodes]

As the electrodes of the organic light-emitting element, a pair of electrodes can be used. The pair of electrodes may be an anode and a cathode. In a case where an electric field is applied in the direction in which the organic light-emitting element emits light, an electrode having a high potential is the anode, and the other is the cathode. It can also be said that an electrode that supplies holes to a light-emitting layer is the anode, and an electrode that supplies electrons to the light-emitting layer is the cathode.

It is desirable that the constituent material of the anode have as great a work function as possible. For example, a metal simple substance such as gold, platinum, silver, copper, nickel, palladium, cobalt, selenium, vanadium, or tungsten, or a mixture containing these can be used for the anode. Alternatively, an alloy obtained by combining these metal simple substances, or a metal oxide such as tin oxide, zinc oxide, indium oxide, indium tin oxide (ITO), or indium zinc oxide may be used for the anode. A conductive polymer such as polyaniline, polypyrrole, or polythiophene can also be used for the anode.

Any of these electrode materials may be used alone, or two or more types of these materials may be used in combination. The anode may be composed of a single layer, or may be composed of a plurality of layers.

In a case where either of the electrodes of the organic light-emitting element is configured as a reflection electrode, for example, chromium, aluminum, silver, titanium, tungsten, molybdenum, an alloy of these, or a laminate of these can be used as the electrode material. With the above materials, the anode can also function as a reflection film that does not have a role as an electrode. In a case where the anode is used as a transparent electrode, an oxide transparent conductive layer made of indium tin oxide (ITO) or indium zinc oxide can be used. The present disclosure, however, is not limited to these. A photolithographic technique can be used to form the electrodes.

On the other hand, it is desirable that the constituent material of the cathode have a small work function. For example, an alkali metal such as lithium, an alkaline earth metal such as calcium, a metal simple substance such as aluminum, titanium, manganese, silver, lead, or chromium, or a mixture containing these can be used. Alternatively, an alloy obtained by combining these metal simple substances can also be used. For example, magnesium-silver, aluminum-lithium, aluminum-magnesium, silver-copper, or zinc-silver can be used. A metal oxide such as indium tin oxide (ITO) can also be used. One type of these electrode substances may be used alone, or two or more types of these electrode substances may be used in combination. The cathode may be composed of a single layer, or may be composed of multiple layers. It is desirable to use silver among these. To reduce the clumping of silver, it is more desirable to use a silver alloy. The ratio of the alloy does not matter so long as the clumping of silver can be reduced. For example, the ratio of silver to the other metal may be 1:1 or 3:1.

The cathode may be a top emission element using an oxide conductive layer made of ITO, or may be a bottom emission element using a reflection electrode made of aluminum (Al). The cathode is not particularly limited. Although a method for forming the cathode is not particularly limited, it is more desirable to use a direct current and alternating current sputtering method because this results in excellent coverage of a film and facilitates a reduction in resistance.

### [Pixel Separation Layer]

A pixel separation layer is formed of a silicon nitride (SiN) film, a silicon oxynitride (SiON) film, or a silicon oxide (SiO) film formed using a chemical vapor deposition (CVD) method.

To increase the resistance of the organic compound layer in the in-plane direction, it is desirable that a film of the organic compound layer, particularly a hole transport layer, be formed to be thin on a side wall of the pixel separation layer. Specifically, the taper angle of the side wall of the pixel separation layer and the film thickness of the pixel separation layer are made great, thereby increasing vignetting when vapor deposition is performed. Thus, it is possible to form a film of the organic compound layer such that the film thickness of the side wall is thin.

On the other hand, it is desirable that the taper angle of the side wall of the pixel separation layer and the film thickness of the pixel separation layer be adjusted to such an extent that a gap is not formed on a protection layer formed on the pixel separation layer. Since a gap is not formed on the protection layer, it is possible to reduce the occurrence of a defect in the protection layer. Since the occurrence of a defect is reduced in the protection layer, it is possible to reduce a decrease in reliability such as the occurrence of a dark spot or the occurrence of a conduction failure in the second electrode.

### [Organic Compound Layer]

The organic compound layer of the organic light-emitting element may be formed of a single layer, or may be formed of a plurality of layers. In a case where the organic compound layer includes a plurality of layers, the plurality of layers may be referred to as a “hole injection layer”, a “hole transport layer”, an “electron blocking layer”, a “light-emitting layer”, a “hole blocking layer”, an “electron transport layer”, and an “electron injection layer” according to their functions. The organic compound layer is composed mainly of an organic compound, but may include an inorganic atom or an inorganic compound. For example, the organic compound layer may include copper, lithium, magnesium, aluminum, iridium, platinum, molybdenum, or zinc. The organic compound layer may be placed between the first and second electrodes, and may be disposed in contact with the first and second electrodes.

### [Protection Layer]

In the organic light-emitting element according to the present exemplary embodiment, a protection layer may be provided on the second electrode. For example, glass in which a moisture absorbent is provided is bonded onto the second electrode, whereby it is possible to reduce the entry of water into the organic compound layer and reduce the occurrence of a display failure. As another exemplary embodiment, a passivation film made of silicon nitride may be provided on the cathode, thereby reducing the entry of water into the organic compound layer. For example, after the cathode is formed, the resulting product may be conveyed to another chamber without breaking a vacuum, and a silicon nitride film having a thickness of 2 micrometers (μm) may be formed by the CVD method, thereby obtaining a protection layer. After the film is formed by the CVD method, a protection layer may be provided using an atomic layer deposition (ALD) method. The material of the film formed by the ALD method is not limited, but may be silicon nitride, silicon oxide, or aluminum oxide. On the film formed by the ALD method, silicon nitride may be further formed by the CVD method. The film thickness of the film formed by the ALD method may be smaller than that of the film formed by the CVD method. Specifically, the film thickness of the film formed by the ALD method may be 50% or less, or further, may be 10% or less.

### [Color Filter]

In the organic light-emitting element according to the present exemplary embodiment, a color filter may be provided on the protection layer. For example, a color filter taking into account the size of the organic light-emitting element may be provided on another substrate, and this substrate and the substrate on which the organic light-emitting element is provided may be bonded together. Alternatively, a color filter may be patterned on the protection layer using a photolithographic technique. The color filter may be composed of high molecules.

### [Planarization Layer]

In the organic light-emitting element according to the present exemplary embodiment, a planarization layer may be included between the color filter and the protection layer. The planarization layer is provided for the purpose of reducing unevenness on a layer below the planarization layer. In a case where the purpose of the planarization layer is not limited, the planarization layer may also be referred to as a “resin layer”. The planarization layer may be composed of an organic compound, and may be composed of low molecules or high molecules. It is, however, desirable that the planarization layer be composed of high molecules.

Planarization layers may be provided above and below the color filter. The constituent materials of the planarization layers may be the same as or different from each other. Specifically, examples of the constituent materials of the planarization layers include a polyvinyl carbazole resin, a polycarbonate resin, a polyester resin, an acrylonitrile butadiene styrene (ABS) resin, an acrylic resin, a polyimide resin, a phenolic resin, an epoxy resin, a silicon resin, and a urea resin.

### [Microlens]

The organic light-emitting element may include an optical member such as a microlens on its light exit side. The microlens can be composed of an acrylic resin or an epoxy resin. The microlens may be provided for the purpose of increasing the amount of light to be extracted from the organic light-emitting element and controlling the direction of light to be extracted from the organic light-emitting element. The microlens may have a hemispherical shape. In a case where the microlens has a hemispherical shape, there is a tangent parallel to the insulating layer among tangents touching the hemisphere, and the point of contact of the tangent and the hemisphere is the apex of the microlens. The apex of the microlens can also be similarly determined in any cross-sectional view. That is, there is a tangent parallel to the insulating layer among tangents touching a semicircle of the microlens in a cross-sectional view, and the point of contact of the tangent and the semicircle is the apex of the microlens.

The midpoint of the microlens can also be defined. In a cross section of the microlens, a line segment from the point where the shape of a circular arc ends to the point where the shape of another circular arc ends is virtualized, and the midpoint of the line segment can be referred to as “the midpoint of the microlens”. The cross sections for determining the apex and the midpoint may be cross sections perpendicular to the insulating layer.

The microlens includes a first surface including a protruding portion, and a second surface opposite to the first surface. It is desirable that the second surface be disposed on the functional layer side of the first surface. To employ this configuration, it is preferable to form the microlens on the light-emitting element. In a case where a functional layer is an organic layer, it is desirable to avoid a process at high temperature in a manufacturing process. In a case where the configuration in which the second surface is disposed on the functional layer side of the first surface is employed, it is desirable that the glass-transition temperatures of all organic compounds constituting an organic layer be 100° C. or more. It is more desirable that the glass-transition temperatures be 130° C. or more.

### [Opposing Substrate]

In the organic light-emitting element according to the present exemplary embodiment, an opposing substrate may be included on the planarization layer. The opposing substrate is termed “opposing substrate” because the opposing substrate is provided at a position corresponding to the substrate. The constituent material of the opposing substrate may be the same as that of the substrate. If the substrate is a first substrate, the opposing substrate can be a second substrate.

### [Organic Layer]

The organic compound layer (a hole injection layer, a hole transport layer, an electron blocking layer, a light-emitting layer, a hole blocking layer, an electron transport layer, and an electron injection layer) included in the organic light-emitting element according to the present exemplary embodiment is formed by a method illustrated below.

The organic compound layer included in the organic light-emitting element according to the present exemplary embodiment can be formed using a vacuum vapor deposition method, an ionized vapor deposition method, or a sputtering or plasma dry process. Instead of the dry process, a wet process for forming the layer by dissolving a material into an appropriate solvent and performing a known application method (e.g., spin coating, dipping, a casting method, a Langmuir-Blodgett (LB) method, or an inkjet method) can also be used.

If the layer is formed by the vacuum vapor deposition method or the solution application method, crystallization is less likely to occur, and the stability over time is excellent. In a case where the film is formed by the application method, the film can also be formed in combination with an appropriate binder resin.

Examples of the binder resin include a polyvinyl carbazole resin, a polycarbonate resin, a polyester resin, an ABS resin, an acrylic resin, a polyimide resin, a phenolic resin, an epoxy resin, a silicon resin, and a urea resin, but are not limited to these. One type of these binder resins may be used alone as a homopolymer or a copolymer, or two or more types of these binder resins may be used in a mixed manner. Further, an additive such as a known plasticizer, a known antioxidant, or a known ultraviolet absorber may be used in combination, where desired.

### [Pixel Circuit]

A light-emitting device including the organic light-emitting element according to the present exemplary embodiment may include a pixel circuit connected to an organic light-emitting element. The pixel circuit may be an active-matrix circuit that independently controls light emission from a first organic light-emitting element and a second organic light-emitting element. The active-matrix circuit may be voltage-programmed or current-programmed. A driving circuit includes the pixel circuit with respect to each pixel. The pixel circuit may include an organic light-emitting element, a transistor that controls the light emission luminance of the organic light-emitting element, a transistor that controls the light emission timing, a capacitor that holds the gate voltage of the transistor that controls the light emission luminance, and a transistor that connects to the ground (GND) not via the light-emitting element.

The light-emitting device includes a display region and a peripheral region disposed around the display region. The light-emitting device includes the pixel circuit in the display region and includes a display control circuit in the peripheral region. The mobility of each transistor included in the pixel circuit may be smaller than the mobility of each transistor included in the display control circuit.

The slope of the current-voltage characteristic of each transistor included in the pixel circuit may be smaller than the slope of the current-voltage characteristic of each transistor included in the display control circuit. The slope of the current-voltage characteristic can be measured based on a so-called Vg-Ig characteristic. Each transistor included in the pixel circuit is a transistor connected to a light-emitting element such as the first organic light-emitting element.

### [Pixels]

The organic light-emitting element according to the present exemplary embodiment includes a plurality of pixels. The pixels include sub-pixels that emit light of colors different from each other. For example, the sub-pixels may have red, green, and blue (RGB) light emission colors. Each pixel emits light in a region also referred to as a “pixel aperture”. This region is the same as a first region. The pixel aperture may be 15 μm or less, or may be 5 μm or more. More specifically, the pixel aperture may be 11 μm, 9.5 μm, 7.4 μm, or 6.4 μm. The distance between sub-pixels may be 10 μm or less, and specifically, may be 8 μm, 7.4 μm, 6.4 μm, or 5.0 μm.

The pixels can take a known arrangement form in a plan view. For example, the known arrangement form may be the stripe arrangement, the delta arrangement, the PenTile arrangement, or the Bayer arrangement. The shape of each sub-pixel in the plan view may take any known shape. For example, the shape of the sub-pixel is a quadrangle such as a rectangle or a rhombus, or a hexagon. For example, the shape of the sub-pixel is included in the rectangle if the shape is close to a rectangle. Each pixel can be configured by combining the shape of the sub-pixel and the pixel arrangement.

### [Application of Organic Light-Emitting Element]

The organic light-emitting element according to the present exemplary embodiment can be used as a component member of a display apparatus or an illumination apparatus. Alternatively, examples of the application of the organic light-emitting element include an exposure light source of an electrophotographic image forming apparatus, a backlight of a liquid crystal display apparatus, or a light-emitting device including a color filter in a white light source.

The display apparatus may be an image information processing apparatus that includes an image input unit to which image information from an area charge-coupled device (CCD), a linear CCD, or a memory card is input, includes an information processing unit that processes the input information, and displays an input image on a display unit.

A display unit included in an imaging apparatus or an inkjet printer may have a touch panel function. A method for driving the touch panel function may be an infrared method, a capacitive method, a resistive method, or an electromagnetic induction method, and is not particularly limited. The display apparatus may also be used in a display unit of a multifunction printer.

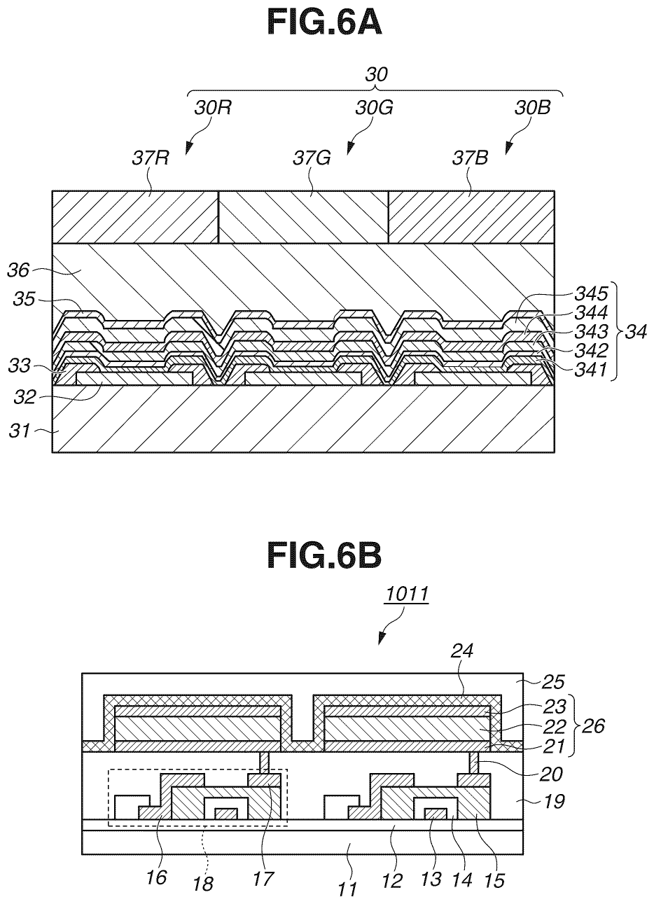

Next, with reference to the drawings, a display apparatus including the organic light-emitting element according to the present exemplary embodiment is described. FIGS. 6A and 6B are schematic cross-sectional views illustrating examples of a display apparatus including an organic light-emitting element and a transistor connected to the organic light-emitting element. The transistor is an example of an active element. The transistor may be a thin-film transistor (TFT).

FIG. 6A is an example of a pixel as a component of the display apparatus including the organic light-emitting element according to the present exemplary embodiment. The pixel includes a sub-pixel 30. The sub-pixel 30 is divided into sub-pixels 30R, 30G, and 30B based on light emission from the sub-pixel 30. The light emission colors may be distinguished based on wavelengths at which light is emitted from a light-emitting layer, or light emitted from the sub-pixel 30 may be selectively transmitted or subjected to color conversion using a color filter. Each of the sub-pixels 30R, 30G, and 30B includes a reflection electrode 32 as a first electrode, and an insulating layer 33 that covers the ends of the reflection electrode 32 on an interlayer insulating layer 31. Further, each of the sub-pixels 30R, 30G, and 30B includes an organic compound layer 34 that covers the reflection electrode 32 and the insulating layer 33, a transparent electrode 35 as a second electrode, a protection layer 36, and color filters 37R, 37G, and 37B.

On a layer below the interlayer insulating layer 31 or within the interlayer insulating layer 31, a transistor and a capacitor element may be disposed. The transistor and the first electrode 32 may be electrically connected together via a contact hole (not illustrated).

The insulating layer 33 is also referred to as a “bank” or a “pixel separation film”. The insulating layer 33 covers the ends of the first electrode 32 and is disposed around the first electrode 32. A portion where the insulating layer 33 is not disposed is in contact with the organic compound layer 34 and forms a light emission region. The organic compound layer 34 includes a hole injection layer 341, a hole transport layer 342, a first light-emitting layer 343, a second light-emitting layer 344, and an electron transport layer 345.

The transparent electrode 35 may be a transparent electrode, a reflection electrode, or a semi-transmissive electrode as the second electrode. The protection layer 36 reduces the penetration of moisture into the organic compound layer 34. Although the protection layer 36 is illustrated as a single layer in FIG. 6A, the protection layer 36 may include a plurality of layers. Each layer may be an inorganic compound layer or an organic compound layer. The color filter is divided into the color filters 37R, 37G, and 37B according to its colors. The color filter may be formed on a planarization film (not illustrated). A resin protection layer (not illustrated) may be disposed on the color filter. The color filter may be formed on the protection layer 36. Alternatively, after the color filter is provided on an opposing substrate such as a glass substrate, the opposing substrate and this substrate may be bonded together.

FIG. 6B illustrates a display apparatus 1011 including the organic light-emitting element according to the present exemplary embodiment. The display apparatus 1011 includes an organic light-emitting element 26 and a TFT 18 as an example of a transistor. A substrate 11 made of glass or silicon is provided, and an insulating layer 12 is provided above the substrate 11. On the insulating layer 12, the active element 18 such as a TFT is disposed, and a gate electrode 13, a gate insulating film 14, and a semiconductor layer 15 of the active element 18 are placed. The TFT 18 also includes a drain electrode 16 and a source electrode 17. Above the TFT 18, an insulating film 19 is provided. An anode 21 included in the organic light-emitting element 26 and the source electrode 17 are connected together via a contact hole 20 provided in the insulating film 19.

A method for electrically connecting an electrode (the anode 21 or a cathode 23) included in the organic light-emitting element 26 and an electrode (the source electrode 17 or the drain electrode 16) included in the TFT 18 is not limited to the form illustrated in FIG. 6B. That is, either one of the anode 21 and the cathode 23 may only need to be electrically connected to either one of the source electrode 17 and the drain electrode 16 of the TFT 18. A “TFT” refers to a thin-film transistor.

Although an organic compound layer 22 is illustrated as a single layer in the display apparatus 1011 in FIG. 6B, the display apparatus 1011 may include a plurality of organic compound layers 22. On the cathode 23, a first protection layer 24 and a second protection layer 25 for reducing the deterioration of the organic light-emitting element 26 are provided.

Although a transistor is used as a switching element in the display apparatus 1011 in FIG. 6B, the transistor may be used as another switching element instead. The transistor used in the display apparatus 1011 in FIG. 6B is not limited to a transistor using a monocrystalline silicon wafer, and may be a thin-film transistor including an active layer on an insulating surface of the substrate. Examples of the active layer include monocrystalline silicon, amorphous silicon, non-monocrystalline silicon such as microcrystalline silicon, and non-monocrystalline oxide semiconductors made of indium zinc oxide and indium gallium zinc oxide. The thin-film transistor is also referred to as a “TFT element”.

The transistor included in the display apparatus 1011 in FIG. 6B may be formed in a substrate such as a silicon (Si) substrate. That the transistor is formed in the substrate means that the transistor is prepared by processing the substrate such as an Si substrate itself. That is, that the transistor is included in the substrate may mean that the substrate and the transistor are integrally formed.

The light emission luminance of the organic light-emitting element according to the present exemplary embodiment is controlled by a TFT as an example of a switching element, and organic light-emitting elements are provided in a plurality of surfaces, whereby it is possible to display images with the light emission luminances of the respective organic light-emitting elements. The switching element according to the present exemplary embodiment is not limited to a TFT, and may be a transistor formed of low-temperature polysilicon or an active-matrix driver formed on a substrate such as an Si substrate. “On a substrate” can also be said to be “in the substrate”. Whether to provide the transistor in a substrate or use a TFT is selected according to the size of the display unit. If the size of the display unit is about 0.5 inches, for example, it is desirable to provide the organic light-emitting element on an Si substrate.

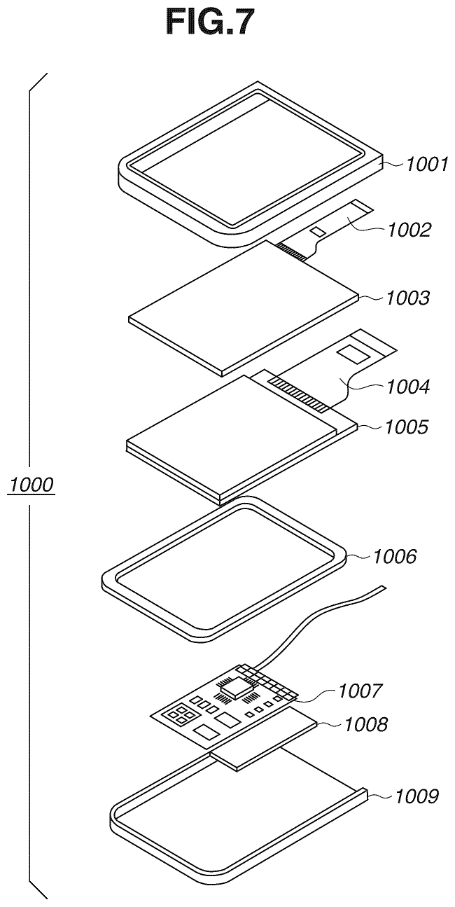

Next, FIG. 7 illustrates a schematic diagram illustrating an example of a display apparatus including the organic light-emitting element according to the present exemplary embodiment. A display apparatus 1000 may include a touch panel 1003, a display panel 1005, a frame 1006, a circuit substrate 1007, and a battery 1008 between an upper cover 1001 and a lower cover 1009. The touch panel 1003 and the display panel 1005 are connected to flexible printed circuits (FPCs) 1002 and 1004, respectively. On the circuit substrate 1007, a transistor is printed. The battery 1008 may not be provided unless the display apparatus 1000 is a mobile device, or may be provided at another position even if the display apparatus 1000 is a mobile device.

The display apparatus 1000 may include color filters having red, green, and blue colors. In the color filters, the red, green, and blue colors may be arranged in the delta arrangement. The display apparatus 1000 may also be used in a display unit of a mobile terminal. At this time, the display apparatus 1000 may have both a display function and an operation function. Examples of the mobile terminal include a mobile phone such as a smartphone, a tablet, and a head-mounted display.

The display apparatus 1000 may also be used in a display unit of an imaging apparatus including an optical unit that includes a plurality of lenses, and an imaging element that receives light passing through the optical unit. The imaging apparatus may include a display unit that displays information acquired by the imaging element. The display unit may be a display unit exposed to outside the imaging apparatus, or may be a display unit placed in a viewfinder. The imaging apparatus may be a digital camera or a digital video camera.

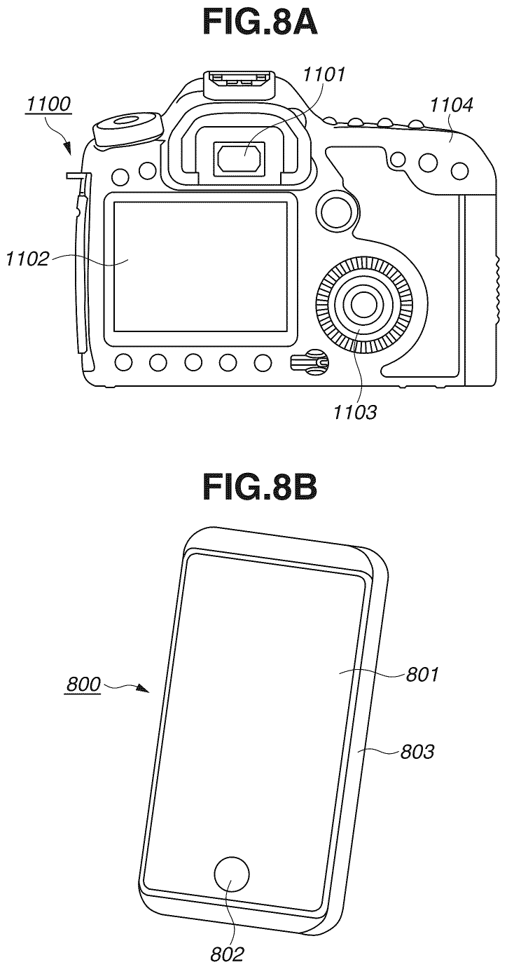

Next, FIG. 8A illustrates a schematic diagram illustrating an example of an imaging apparatus including the organic light-emitting element according to the present exemplary embodiment. An imaging apparatus 1100 may include a viewfinder 1101, a back surface display 1102, an operation unit 1103, and a housing 1104. The viewfinder 1101 may include a display apparatus according to the present exemplary embodiment. In this case, the display apparatus may display not only a captured image, but also environment information and an image capturing instruction. The environment information may include the intensity of external light, the direction of external light, the moving speed of an object, and the possibility that an object is blocked by a blocking object.

Since a timing suitable for capturing an image lasts for a short time, it is desirable that the information be displayed as soon as possible. Thus, it is desirable to configure a display apparatus of which the response speed is fast, using the organic light-emitting element according to the present exemplary embodiment. The display apparatus using the organic light-emitting element can be used more suitably than these apparatuses and a liquid crystal display apparatus, which require a fast display speed.

The imaging apparatus 1100 includes an optical unit (not illustrated). The optical unit includes a plurality of lenses and forms an image on an imaging element accommodated in the housing 1104. The focus can be adjusted by adjusting the relative positions of the plurality of lenses. This operation can also be performed automatically. The imaging apparatus 1100 may also be referred to as a “photoelectric conversion apparatus”. The photoelectric conversion apparatus can include a method for detecting the difference from the previous image without sequentially capturing images or a method for clipping an image from an always recorded image as an imaging method.

FIG. 8B is a schematic diagram illustrating an example of an electronic device including the organic light-emitting element according to the present exemplary embodiment. An electronic device 800 includes a display unit 801, an operation unit 802, and a housing 803. The housing 803 may include a circuit, a printed substrate including the circuit, a battery, and a communication unit. The operation unit 802 may be a button, or may be a response unit using a touch panel method. The operation unit 802 may be a biometric unit that recognizes a fingerprint and releases a lock. The electronic device 800 including the communication unit can also be said to be a communication device. The electronic device 800 may further have a camera function by including a lens and an imaging element. An image captured by the camera function is displayed on the display unit 801. Examples of the electronic device 800 include a smartphone and a laptop personal computer.

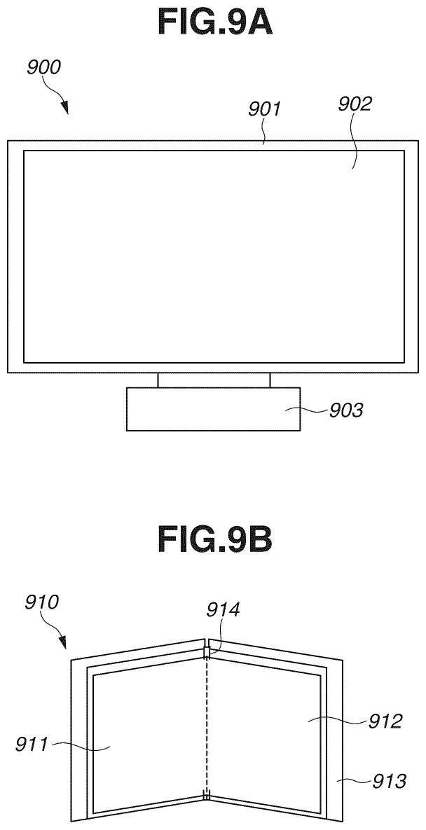

Next, FIG. 9A illustrates a schematic diagram illustrating an example of a display apparatus including the organic light-emitting element according to the present exemplary embodiment. FIG. 9A illustrates a display apparatus 900 such as a television monitor or a personal computer (PC) monitor. The display apparatus 900 includes a frame 901 and a display unit 902. The organic light-emitting element according to the present exemplary embodiment may be used in the display unit 902. The display apparatus 900 also includes a base 903 that supports the frame 901 and the display unit 902. The base 903 is not limited to the form in FIG. 9A. The lower side of the frame 901 may double as a base. The frame 901 and the display unit 902 may be curved. The radius of curvature of the curve may be 5000 millimeters (mm) or more and 6000 mm or less.

FIG. 9B is a schematic diagram illustrating another example of the display apparatus including the organic light-emitting element according to the present exemplary embodiment. A display apparatus 910 in FIG. 9B is configured to be folded and is a so-called foldable display apparatus. The display apparatus 910 includes a first display unit 911, a second display unit 912, a housing 913, and a folding point 914. The first display unit 911 and the second display unit 912 may include the organic light-emitting element according to the present exemplary embodiment. The first display unit 911 and the second display unit 912 may be a single display apparatus without a joint. The first display unit 911 and the second display unit 912 can be divided at the folding point 914. The first display unit 911 and the second display unit 912 may display images different from each other, or may display a single image.

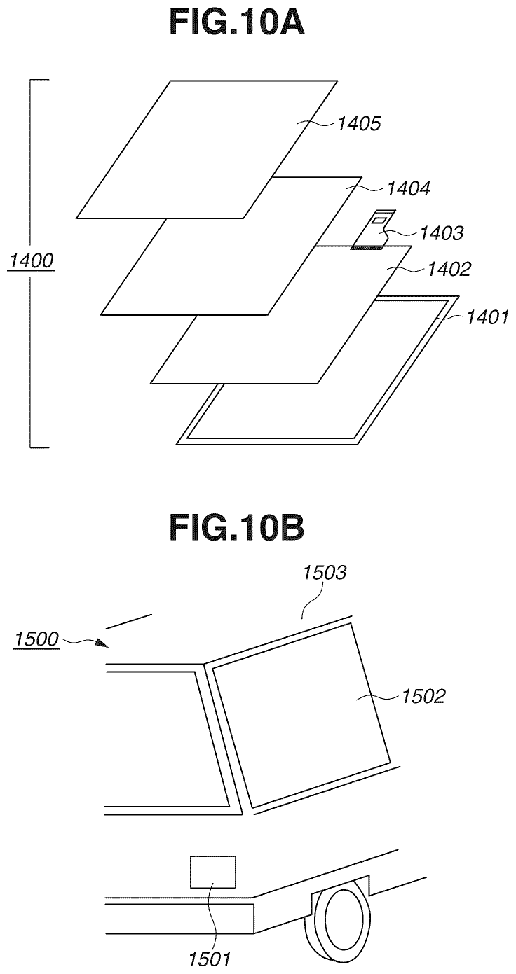

Next, FIG. 10A illustrates a schematic diagram illustrating an example of an illumination apparatus including the organic light-emitting element according to the present exemplary embodiment. An illumination apparatus 1400 may include a housing 1401, a light source 1402, a circuit substrate 1403, an optical film 1404, and a light diffusion portion 1405. The light source 1402 may include the organic light-emitting element according to the present exemplary embodiment. The optical film 1404 may be a filter for improving the color rendering properties of the light source 1402. The light diffusion portion 1405 can effectively diffuse light of the light source 1402 by lighting up and deliver light to a wide range. The optical film 1404 and the light diffusion portion 1405 may be provided on the light exit side of illumination. A cover may be provided in an outermost portion of the illumination apparatus 1400, where desired.

For example, the illumination apparatus 1400 is an apparatus that illuminates the inside of a room. The illumination apparatus 1400 may emit light of white, daylight white, or any of colors from blue to red. The illumination apparatus 1400 may include a light modulation circuit that modulates the light. For example, the illumination apparatus 1400 may include the organic light-emitting element according to the present exemplary embodiment and a power supply circuit connected to the organic light-emitting element. The power supply circuit is a circuit that converts an alternating-current voltage into a direct-current voltage. The color temperature of white is 4200 K, and the color temperature of daylight white is 5000 K. The illumination apparatus 1400 may also include a color filter. The illumination apparatus 1400 may also include a heat release portion. The heat release portion releases heat in the apparatus to outside the apparatus. Examples of the heat release portion include a metal having high specific heat and liquid silicon.

FIG. 10B is a schematic diagram illustrating an automobile as an example of a moving object including the organic light-emitting element according to the present exemplary embodiment. The automobile includes a taillight as an example of a lamp fitting. An automobile 1500 may include a taillight 1501 and have a form in which when a brake operation is performed, the automobile 1500 lights up the taillight 1501.

The taillight 1501 includes the organic light-emitting element according to the present exemplary embodiment. The taillight 1501 may include a protection member that protects an organic electroluminescent (EL) element. The material of the protection member does not matter so long as the material has somewhat high strength and is transparent. It is, however, desirable that the protection member be composed of polycarbonate. The polycarbonate may be mixed with a furandicarboxylic acid derivative or an acrylonitrile derivative.

The automobile 1500 may include a vehicle body 1503 and a window 1502 attached to the vehicle body 1503. The window 1502 may be a transparent display unless the window 1502 is used for viewing and checking the front and the rear of the automobile 1500. The transparent display may include the organic light-emitting element according to the present exemplary embodiment. In this case, the constituent material of an electrode included in the organic light-emitting element is composed of a transparent member.

The moving object including the organic light-emitting element according to the present exemplary embodiment may also be a vessel, an aircraft, or a drone. The moving object may include a body and a lamp fitting provided in the body. The lamp fitting may emit light to notify a user of the position of the body. The lamp fitting includes the organic light-emitting element according to the present exemplary embodiment.

A display apparatus including the organic light-emitting element according to the present exemplary embodiment can be applied to a system that can be worn as a wearable device such as smart glasses, a head-mounted display (HMD), or smart contact lenses. An imaging display apparatus used in such application examples includes an imaging apparatus capable of photoelectrically converting visible light and a display apparatus capable of emitting visible light.

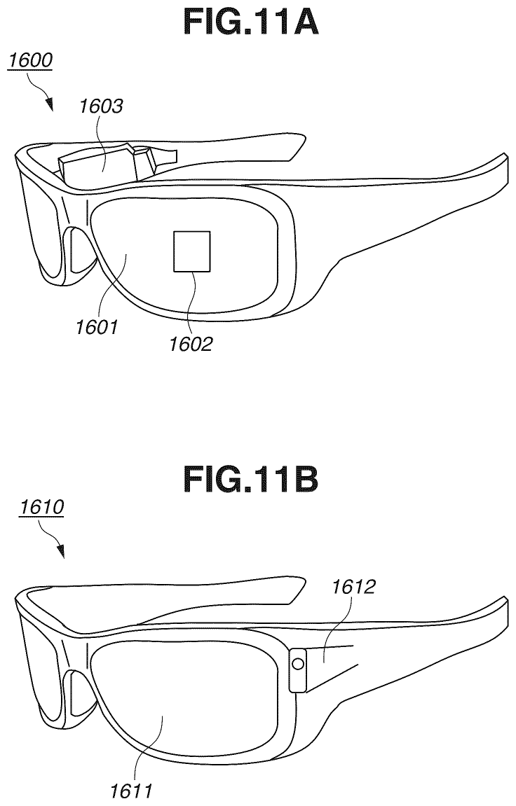

Next, FIG. 11A illustrates eyeglasses 1600 (smart glasses) according to an application example of the display apparatus including the organic light-emitting element according to the present exemplary embodiment. On a front surface of a lens 1601 of the eyeglasses 1600, an imaging apparatus 1602 such as a complementary metal-oxide-semiconductor (CMOS) sensor or a single-photon avalanche diode (SPAD) is provided. On a back surface of the lens 1601, the display apparatus according to each of the above exemplary embodiments is provided.

The eyeglasses 1600 further include a control apparatus 1603. The control apparatus 1603 functions as a power supply that supplies power to the imaging apparatus 1602 and the display apparatus according to each of the exemplary embodiments. The control apparatus 1603 controls the operations of the imaging apparatus 1602 and the display apparatus. In the lens 1601, an optical system for collecting light on the imaging apparatus 1602 is formed.

FIG. 11B illustrates eyeglasses 1610 (smart glasses) according to another application example of the display apparatus including the organic light-emitting element according to the present exemplary embodiment. The eyeglasses 1610 include a control apparatus 1612. On the control apparatus 1612, an imaging apparatus equivalent to the imaging apparatus 1602 and the display apparatus are mounted. In a lens 1611, an optical system for projecting light emitted from the display apparatus in the control apparatus 1612 is formed. An image is projected onto the lens 1611. The control apparatus 1612 functions as a power supply that supplies power to the imaging apparatus and the display apparatus, and also controls the operations of the imaging apparatus and the display apparatus. The control apparatus 1612 may include a line-of-sight detection unit that detects the line of sight of a wearer (a user). The line of sight may be detected using infrared light. An infrared light-emitting unit emits infrared light to the eyeball of the user gazing at the display image. An imaging unit including a light-receiving element detects reflected light of the emitted infrared light from the eyeball, thereby obtaining a captured image of the eyeball. The control apparatus 1612 includes a reduction unit that reduces light from the infrared light-emitting unit to a display unit in a plan view, thereby reducing a decrease in the grade of the image.

The line of sight of the user to the display image is detected from the captured image of the eyeball obtained by capturing the infrared light. Any known technique can be applied to the line-of-sight detection using the captured image of the eyeball. As an example, a line-of-sight detection method based on a Purkinje image formed by the reflection of emitted light from the cornea can be used.

More specifically, a line-of-sight detection process based on a pupil-corneal reflection method is performed. Using the pupil-corneal reflection method, a line-of-sight vector indicating the direction (the rotation angle) of the eyeball is calculated based on an image of the pupil and a Purkinje image included in the captured image of the eyeball, thereby detecting the line of sight of the user.

A display apparatus including the organic light-emitting element according to the present exemplary embodiment may include an imaging apparatus including a light-receiving element and control a display image on the display apparatus based on line-of-sight information regarding a user from the imaging apparatus.

Specifically, based on the line-of-sight information, the display apparatus determines a first field-of-view region gazed at by the user and a second field-of-view region other than the first field-of-view region. The first and second field-of-view regions may be determined by a control apparatus of the display apparatus, or the display apparatus may receive the first and second field-of-view regions determined by an external control apparatus. In a display region of the display apparatus, the display resolution of the first field-of-view region may be controlled to be higher than the display resolution of the second field-of-view region. That is, the resolution of the second field-of-view region may be set to be lower than that of the first field-of-view region.

The display region includes a first display region and a second display region different from the first display region, and based on the line-of-sight information, the display apparatus may select a region having high priority between the first and second display regions. The first and second display regions may be determined by the control apparatus of the display apparatus, or the display apparatus may receive the first and second display regions determined by the external control apparatus. The display apparatus may also control the resolution of the region having high priority to be higher than the resolution of the region other than the region having high priority. That is, the display apparatus may set the resolution of the region having relatively low priority to be low.

The display apparatus may determine the first field-of-view region and the region having high priority using artificial intelligence (AI). The AI may be a model configured to, using as supervised data an image of an eyeball and a direction actually viewed by the eyeball in the image, estimate the angle of the line of sight and the distance to an object in the line of sight based on an image of an eyeball. An AI program may be included in the display apparatus, or may be included in the imaging apparatus, or may be included in an external apparatus. In a case where the AI program is included in the external apparatus, the AI program is transmitted from the external apparatus to the display apparatus through communication.

In a case where the display apparatus performs display control based on line-of-sight detection, the display apparatus can be suitably applied to smart glasses further including an imaging apparatus that captures outside. The smart glasses can display information regarding the captured outside in real time.

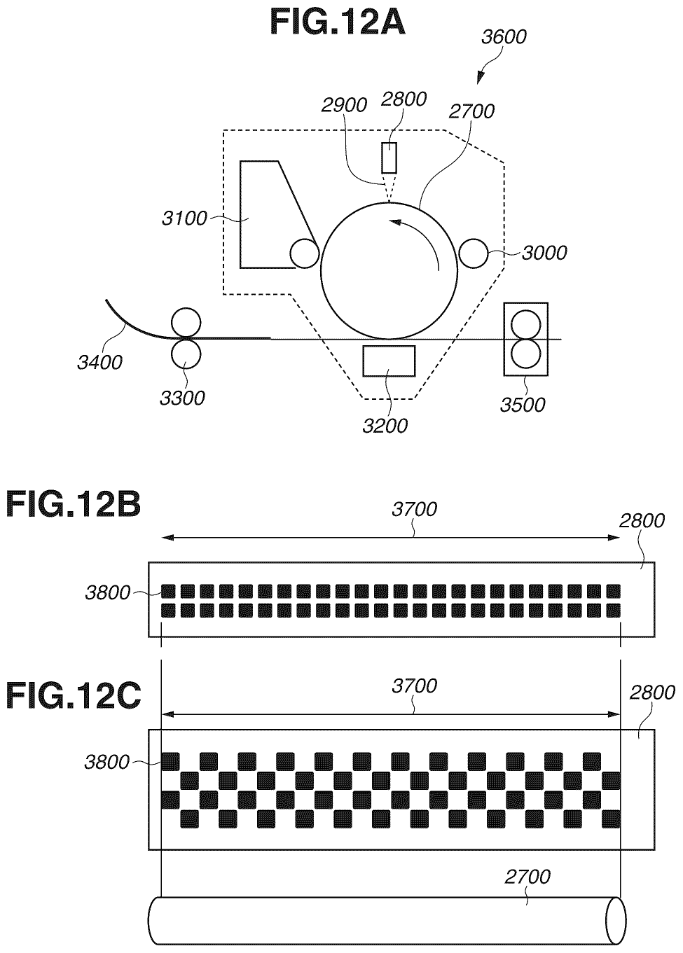

FIGS. 12A, 12B, and 12C illustrate an image forming apparatus according to an exemplary embodiment of the present disclosure. FIG. 12A is a schematic diagram illustrating an image forming apparatus 3600 according to the exemplary embodiment of the present disclosure. The image forming apparatus 3600 includes a photosensitive member 2700, an exposure light source 2800, a development unit 3100, a charging unit 3000, a transfer device 3200, conveyance rollers 3300, and a fixing device 3500.

The exposure light source 2800 emits light 2900, and an electrostatic latent image is formed on the surface of the photosensitive member 2700. The exposure light source 2800 includes the organic light-emitting element according to the present disclosure. The development unit 3100 has toner. The charging unit 3000 charges the photosensitive member 2700. The transfer device 3200 transfers a developed image to a recording medium 3400. The conveyance unit 3300 conveys the recording medium 3400. The recording medium 3400 is paper, for example. The fixing device 3500 fixes the image formed on the recording medium 3400.

FIGS. 12B and 12C are schematic diagrams illustrating the state where a plurality of light-emitting units 3800 is placed on a long substrate in the exposure light source 2800. A direction 3007 indicates a direction parallel to the shaft of the photosensitive member 2700 and indicates the column direction in which organic light-emitting elements are arranged. This column direction is the same as the direction of an axis about which the photosensitive member 2700 rotates. This direction can also be referred to as “the long axis direction of the photosensitive member 2700”.

FIG. 12B illustrates a form in which light-emitting units 3800 are placed along the long axis direction of the photosensitive member 2700. FIG. 12C illustrates a form different from that in FIG. 12B, and is a form in which light-emitting units 3800 are alternately placed in the column direction in each of a first column and a second column. The first and second columns are placed at different positions in the row direction.

In the first column, a plurality of light-emitting units 3800 is placed at intervals. The second column has light-emitting units 3800 at positions corresponding to the intervals between the light-emitting units 3800 in the first column. That is, a plurality of light-emitting units 3800 is placed at intervals also in the row direction.

The arrangement in FIG. 12C can be restated as, for example, the state where the light-emitting units 3800 are arranged in a grid pattern, the state where the light-emitting units 3800 are arranged in a houndstooth pattern, or a checkerboard pattern.

For example, the present disclosure includes the following configurations according to some embodiments.

### (Configuration 1)

A vapor deposition mask comprising:
a mask substrate including a recessed portion disposed on an opposing surface opposed to a substrate, and a peripheral portion surrounding the recessed portion; and
a projection portion disposed in the mask substrate,
wherein a bottom portion of the recessed portion includes a first opening and a second opening adjacent to each other in a first direction, a third opening and a fourth opening adjacent to each other in the first direction and adjacent to the first and second openings in a second direction intersecting the first direction, and a beam portion disposed between the first and second openings, between the third and fourth openings, between the first and third openings, between the second and fourth openings, and between the first and fourth openings,
wherein the projection portion is disposed on an upper surface of the beam portion, and
wherein in a case where in a planar view of the upper surface, a region obtained by combining the first to fourth openings and the beam portion is a first region, and a region having a same area and a same outer shape as an area and an outer shape of the first region in the peripheral portion is a second region, an area of contact of the opposing surface of the second region with a parallel surface parallel to the opposing surface is greater than an area of contact of the opposing surface of the first region with the parallel surface.

### (Configuration 2)

The vapor deposition mask according to Configuration 1, wherein a frictional force of the opposing surface of the second region against the parallel surface is greater than a frictional force of the opposing surface of the first region against the parallel surface.

### (Configuration 3)

The vapor deposition mask according to Configuration 1 or 2, wherein an end of the projection portion and a portion of the peripheral portion including the opposing surface have materials different from each other.

### (Configuration 4)

The vapor deposition mask according to any one of Configurations 1 to 3, wherein an end of the projection portion has a resin, and the opposing surface of the peripheral portion has a metal.

### (Configuration 5)

The vapor deposition mask according to any one of Configurations 1 to 4, wherein in a cross section passing through the projection portion and the beam portion, a distance from an upper surface of the recessed portion to an upper surface of the projection portion in a direction perpendicular to the opposing surface is greater than a distance from the upper surface of the recessed portion to an upper surface of the peripheral portion in the direction perpendicular to the opposing surface.

### (Configuration 6)

The vapor deposition mask according to any one of Configurations 1 to 5,
wherein the first opening is adjacent to the third opening in the second direction,
wherein the second opening is adjacent to the fourth opening in the second direction, and
wherein the projection portion is disposed in a portion of the beam portion between the first and fourth openings.

### (Configuration 7)

The vapor deposition mask according to any one of Configurations 1 to 6, wherein in the planar view, the beam portion has a grid shape in the recessed portion.

### (Configuration 8)

The vapor deposition mask according to Configuration 7,
wherein a plurality of projection portions is present on the upper surface of the beam portion, and
wherein each of the projection portion and the plurality of projection portions is disposed in any of intersection portions of the grid shape.

### (Configuration 9)

The vapor deposition mask according to any one of Configurations 1 to 8, a bottom portion and an upper portion of the peripheral portion have materials different from each other.

### (Configuration 10)

The vapor deposition mask according to any one of Configurations 1 to 9, wherein an end of the projection portion and a portion of the peripheral portion including the opposing surface have a same material.

### (Method 1)

A method for manufacturing an organic electroluminescent (EL) element including at least an organic layer between a first electrode and a second electrode, the method comprising:
opposing a vapor deposition mask and a substrate to each other, the vapor deposition mask comprising:
a mask substrate including a recessed portion disposed on an opposing surface opposed to a substrate, and a peripheral portion surrounding the recessed portion; and
a projection portion disposed in the mask substrate,
wherein a bottom portion of the recessed portion includes a first opening and a second opening adjacent to each other in a first direction, a third opening and a fourth opening adjacent to each other in the first direction and adjacent to the first and second openings in a second direction intersecting the first direction, and a beam portion disposed between the first and second openings, between the third and fourth openings, between the first and third openings, between the second and fourth openings, and between the first and fourth openings,
wherein the projection portion is disposed on an upper surface of the beam portion, and
wherein in a case where in a planar view of the upper surface, a region obtained by combining the first to fourth openings and the beam portion is a first region, and a region having a same area and a same outer shape as an area and an outer shape of the first region in the peripheral portion is a second region,
an area of contact of the opposing surface of the second region with a parallel surface parallel to the opposing surface is greater than an area of contact of the opposing surface of the first region with the parallel surface;
adjusting positions of the substrate and the vapor deposition mask;
bringing the substrate and the vapor deposition mask into contact with each other; and
forming a vapor deposition pattern by vapor-depositing a vapor deposition material on the substrate through an opening of the vapor deposition mask,
wherein the substrate or the vapor deposition mask is disposed so that the projection portion and a part of the opposing surface of the peripheral portion are in contact with the substrate in bringing the substrate and the vapor deposition mask into contact with each other.

### (Configuration 11)

A vapor deposition mask comprising:
a mask substrate including a recessed portion disposed on an opposing surface opposed to a substrate, and a peripheral portion surrounding the recessed portion; and
a plurality of projection portions disposed in the mask substrate,
wherein a bottom portion of the recessed portion includes a plurality of openings and a beam portion disposed between the plurality of openings,
wherein the plurality of projection portions is disposed on an upper surface of the beam portion, and
wherein a projection portion is not disposed on the opposing surface of the peripheral portion opposed to the substrate.

### (Configuration 12)

The vapor deposition mask according to Configuration 11, wherein ends of the plurality of projection portions and a portion of the peripheral portion including the opposing surface have materials different from each other.

### (Configuration 13)

The vapor deposition mask according to Configuration 11 or 12, wherein ends of the plurality of projection portions have a resin, and the opposing surface of the peripheral portion has a metal.

### (Configuration 14)

The vapor deposition mask according to any one of Configurations 11 to 13, wherein in a cross section passing through at least one of the plurality of projection portions and the beam portion, a distance from an upper surface of the recessed portion to an upper surface of the at least one projection portion in a direction perpendicular to the opposing surface is greater than a distance from the upper surface of the recessed portion to an upper surface of the peripheral portion in the direction perpendicular to the opposing surface.

### (Configuration 15)

The vapor deposition mask according to any one of Configurations 11 to 14,
wherein the plurality of openings includes a first opening and a second opening adjacent to each other in a first direction, and a third opening and a fourth opening adjacent to each other in the first direction,
wherein the first opening is adjacent to the third opening in a second direction intersecting the first direction,
wherein the second opening is adjacent to the fourth opening in the second direction, and
wherein one of the plurality of projection portions is disposed in a portion of the beam portion between the first and fourth openings.

### (Configuration 16)

The vapor deposition mask according to any one of Configurations 11 to 15, wherein in a planar view of the upper surface, the beam portion has a grid shape in the recessed portion.

### (Configuration 17)

The vapor deposition mask according to Configuration 16, wherein each of the plurality of projection portions is disposed in any of intersection portions of the grid shape.

### (Configuration 18)

The vapor deposition mask according to any one of Configurations 11 to 17, wherein a bottom portion and an upper portion of the peripheral portion have materials different from each other.

### (Configuration 19)

The vapor deposition mask according to any one of Configurations 11 to 18, wherein ends of the plurality of projection portions and a portion of the peripheral portion including the opposing surface have a same material.

### (Method 2)

A method for manufacturing an organic electroluminescent (EL) element including at least an organic layer between a first electrode and a second electrode, the method comprising:
opposing a vapor deposition mask and a substrate to each other, the vapor deposition mask comprising:
a mask substrate including a recessed portion disposed on an opposing surface opposed to a substrate, and a peripheral portion surrounding the recessed portion; and
a plurality of projection portions disposed in the mask substrate,
wherein a bottom portion of the recessed portion includes a plurality of openings and a beam portion disposed between the plurality of openings,
wherein the plurality of projection portions is disposed on an upper surface of the beam portion, and
wherein a projection portion is not disposed on the opposing surface of the peripheral portion opposed to the substrate;
adjusting positions of the substrate and the vapor deposition mask;
bringing the substrate and the vapor deposition mask into contact with each other; and
forming a desired vapor deposition pattern by vapor-depositing a vapor deposition material on the substrate through an opening of the vapor deposition mask,
wherein the substrate or the vapor deposition mask is disposed so that the projection portion and a part of the opposing surface of the peripheral portion abut the substrate in a case where the substrate and the vapor deposition mask are brought into contact with each other.

### EXAMPLES

Configuration examples of the present disclosure are described below using examples and comparative examples. A vapor deposition mask according to the present disclosure is not limited to these examples. Regarding vapor deposition masks illustrated in examples 1 to 3 and comparative examples 1 and 2, a vapor deposition material was vapor-deposited on a substrate using each vapor deposition mask, a film of a film formation pattern was formed, and a positional shift in the film formation pattern was evaluated.

### Example 1

Vapor deposition was performed using the vapor deposition mask 100 in FIGS. 1A, 1B, and 1C as a vapor deposition mask according to example 1. As the vapor deposition mask 100 illustrated in this case, the vapor deposition mask 100 prepared by processing a metal plate was used. As an example, the vapor deposition mask 100 was a metal mask having an outer perimeter size of 450×450 mm and a thickness of 0.5 mm. As the metal of the metal mask according to the present example, an invar material was used.

As illustrated in FIG. 1B, in the planar view of the surface of the vapor deposition mask 100 opposed to the substrate 110, the area of the recessed portion 104 was 5300 mm². Further, the projection portions 105 placed in the recessed portion 104 were protruding portions made of a resin formed by applying the resin with a dispenser and were placed at the intersections of the beam portion 108 in the recessed portion 104. As the resin of the protruding portions formed in the present example, a polyimide resin was used.

The peripheral portion 107 of the vapor deposition mask 100 came into contact with the substrate 110, and the area of contact of the peripheral portion 107 with the substrate 110 was 1700 mm². The proportion of the area of contact of the peripheral portion 107 with the substrate 110 was 25%.

### Example 2

Vapor deposition was performed using the vapor deposition mask 300 illustrated in FIGS. 3A and 3B according to the second exemplary embodiment as a vapor deposition mask according to example 2. That is, the vapor deposition mask 300 used in example 2 was similar to the vapor deposition mask 100 according to example 1 except that the material of the portion of the peripheral portion 307 that came into contact with the substrate 110 was a resin. Thus, the portion that came into contact with the substrate 110 in the peripheral portion 307 was made of a polyimide resin.

### Example 3

Vapor deposition was performed using the vapor deposition mask 400 illustrated in FIGS. 4A and 4B according to the second exemplary embodiment as a vapor deposition mask according to example 3. That is, the vapor deposition mask 400 used in example 3 was similar to the vapor deposition mask 100 according to example 1 except that the material of the projection portions 405 was invar, which was the same as that of the portion of the peripheral portion 407 that came into contact with the substrate 110.

### Comparative Example 1

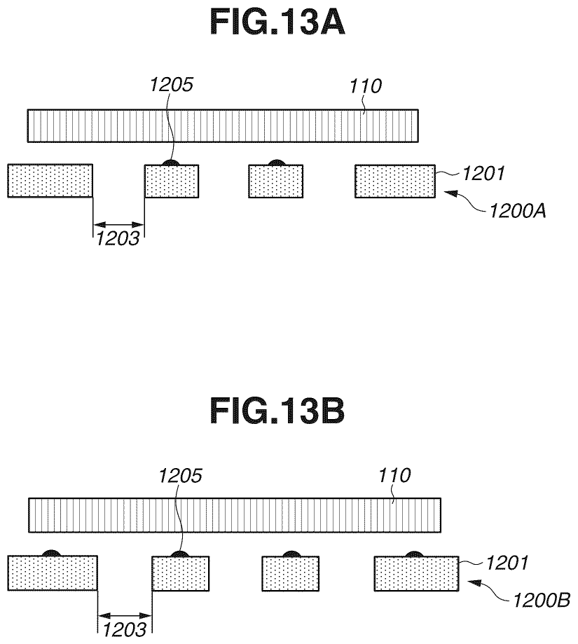

Next, a vapor deposition mask according to comparative example 1 of the present disclosure is described. In a vapor deposition mask 1200A according to comparative example 1, as illustrated in FIG. 13A, a recessed portion surrounding opening portions 1203 was not present in a planar view of the vapor deposition mask 1200A. Structures 1205 placed around the opening portions 1203 were protruding portions made of a resin formed by applying the resin with a dispenser.

The vapor deposition mask 1200A according to comparative example 1 was similar to the vapor deposition mask 100 according to example 1 except that in the vapor deposition mask 1200A, a recessed portion surrounding the opening portions 1203 was not formed.

### Comparative Example 2

In a vapor deposition mask 1200B according to comparative example 2, as illustrated in FIG. 13B, a recessed portion surrounding the opening portions 1203 was not present in a planar view of the vapor deposition mask 1200B, and projection portions 1205 were disposed in the entirety of an opposing surface opposed to the substrate 110.

The vapor deposition mask 1200B according to comparative example 2 was similar to the vapor deposition mask 100 according to example 1 except that in the vapor deposition mask 1200B, a recessed portion surrounding the opening portions 1203 was not formed.

### [Method for Determining Positional Shift in Film Formation and Result of Determination]

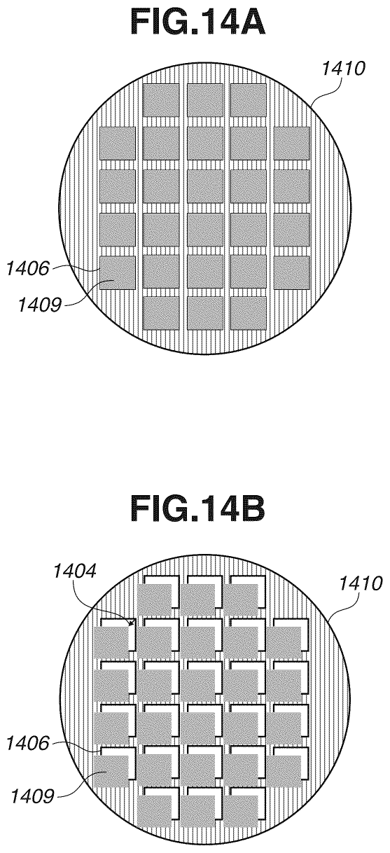

With reference to FIGS. 14A and 14B, a description is given of the evaluation of a positional shift in film formation when vapor deposition is performed. FIGS. 14A and 14B are schematic plan views of the state where a film of a vapor deposition pattern 1409 was formed on a substrate 1410 after vapor deposition was performed using a vapor deposition mask. FIGS. 14A and 14B illustrate desired vapor deposition positions as vapor deposition positions 1406.

As illustrated in FIG. 14A, when a vapor deposition material was vapor-deposited in an effective region on the substrate 1410, the vapor deposition pattern 1409 was vapor-deposited on the desired vapor deposition positions 1406. In such a case, the result of determining a positional shift in film formation was evaluated as “good”. On the other hand, as illustrated in FIG. 14B, when a vapor deposition material was vapor-deposited on the substrate 1410, the vapor deposition pattern 1409 was vapor-deposited on positions shifted from the desired vapor deposition positions 1406. In the present example, in view of the processing accuracy of openings and the alignment accuracy of the substrate 1410 and the vapor deposition mask, if the amount of shift 1404 was 10 μm or more, the result of determining a positional shift in film formation was evaluated as “poor”.

Next, the result of forming a film of a vapor deposition pattern using each of the vapor deposition masks according to examples 1 to 3 and comparative examples 1 and 2 is illustrated.

As the result of vapor-depositing an organic material as a vapor deposition material on the substrate 110 using the vapor deposition mask 100 according to example 1, a positional shift in film formation was less than 10 μm, and the determination result was “good”. At this time, a positional shift in film formation between desired vapor deposition positions on the substrate 110 and a vapor deposition pattern vapor-deposited through the opening portions 103 of all the recessed portions 104 in the vapor deposition mask 100 was less than 10 μm.

As the result of vapor-depositing an organic material as a vapor deposition material on the substrate 110 using the vapor deposition mask 300 according to example 2, a positional shift in film formation was less than 10 μm, and the determination result was “good”. Also at this time, similarly to example 1, a positional shift in film formation between desired vapor deposition positions on the substrate 110 and a vapor deposition pattern vapor-deposited through opening portions 303 of all recessed portions 304 in the vapor deposition mask 300 was less than 10 μm.

As the result of vapor-depositing an organic material as a vapor deposition material on the substrate 110 using the vapor deposition mask 400 according to example 3, a positional shift in film formation was less than 10 μm, and the determination result was “good”. Also at this time, similarly to examples 1 and 2, a positional shift in film formation between desired vapor deposition positions on the substrate 110 and a vapor deposition pattern vapor-deposited through opening portions 403 of all recessed portions 404 in the vapor deposition mask 400 was less than 10 μm.

Next, the result of vapor-depositing an organic material on a substrate 1210 using the vapor deposition mask 1200A according to comparative example 1 is illustrated. At this time, a positional shift in film formation between desired vapor deposition positions on the substrate 1210 and a vapor deposition pattern vapor-deposited through the opening portions 1203 in the vapor deposition mask 1200A was 10 μm or more. Thus, the result of determining the vapor deposition film formation was “poor”.

As the result of vapor-depositing an organic material on the substrate 1210 using the vapor deposition mask 1200B according to comparative example 2, a positional shift in film formation between desired vapor deposition positions on the substrate 1210 and a vapor deposition pattern vapor-deposited through the opening portions 1203 in the vapor deposition mask 1200B was 10 μm or more. Thus, the result of determining the vapor deposition film formation was “poor”.

Table 1 illustrates the result of determining a positional shift in film formation as the result of performing vapor deposition using each of the vapor deposition masks according to examples 1 to 3 and the vapor deposition masks according to comparative examples 1 and 2.

TABLE 1

| | | | | Comparative | Comparative |
|---|---|---|---|---|---|
| | Example 1 | Example 2 | Example 3 | Example 1 | Example 2 |
| Material of Vapor | Metal | Metal | Metal | Metal | Metal |
| Deposition Mask | | | | | |
| Material of | Resin | Resin | Metal | Resin | Resin |
| Projection Portions | | | | | |
| Material of | Metal | Resin | Metal | Metal | Metal |
| Peripheral Portion | | | | | |
| Presence or Absence | Present | Present | Present | Absent | Absent |
| of Recessed Portion | | | | | |
| Presence or Absence | Absent | Absent | Absent | Absent | Present |
| of Projection Portions | | | | | |
| in Peripheral Portion | | | | | |
| Positional Shift in | Good | Good | Good | Poor | Poor |
| Film Formation | (Absent) | (Absent) | (Absent) | (Present) | (Present) |

From these results, it has been found that the masks according to examples 1 to 3 can suitably reduce a positional shift in film formation of a vapor deposition pattern when a film is formed by vacuum vapor deposition, compared to the vapor deposition masks illustrated in comparative examples 1 and 2.

With the above configuration, it is possible to provide a vapor deposition mask in which a positional shift in film formation is reduced when the vapor deposition mask and a substrate are brought into close contact with each other in vapor deposition.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Application No. 2023-209997, filed Dec. 13, 2023, which is hereby incorporated by reference herein in its entirety.

What is claimed is:

1. A vapor deposition mask comprising:
a mask substrate including a recessed portion disposed on an opposing surface opposed to a substrate, and a peripheral portion surrounding the recessed portion; and
a projection portion disposed in the mask substrate,
wherein a bottom portion of the recessed portion includes a first opening and a second opening adjacent to each other in a first direction, a third opening and a fourth opening adjacent to each other in the first direction and adjacent to the first and second openings in a second direction intersecting the first direction, and a beam portion disposed between the first and second openings, between the third and fourth openings, between the first and third openings, between the second and fourth openings, and between the first and fourth openings,
wherein the projection portion is disposed on an upper surface of the beam portion, and
wherein in a case where in a planar view of the upper surface, a region obtained by combining the first to fourth openings and the beam portion is a first region, and a region having a same area and a same outer shape as an area and an outer shape of the first region in the peripheral portion is a second region,
an area of contact of the opposing surface of the second region with a parallel surface parallel to the opposing surface is greater than an area of contact of the opposing surface of the first region with the parallel surface.

2. The vapor deposition mask according to claim 1, wherein a frictional force of the opposing surface of the second region against the parallel surface is greater than a frictional force of the opposing surface of the first region against the parallel surface.

3. The vapor deposition mask according to claim 1, wherein an end of the projection portion and a portion of the peripheral portion including the opposing surface have materials different from each other.

4. The vapor deposition mask according to claim 1, wherein an end of the projection portion has a resin, and the opposing surface of the peripheral portion has a metal.

5. The vapor deposition mask according to claim 1, wherein in a cross section passing through the projection portion and the beam portion, a distance from an upper surface of the bottom portion of the recessed portion to an upper surface of the projection portion in a direction perpendicular to the opposing surface is greater than a distance from the upper surface of the bottom portion to an upper surface of the peripheral portion in the direction perpendicular to the opposing surface.

6. The vapor deposition mask according to claim 1,
wherein the first opening is adjacent to the third opening in the second direction,
wherein the second opening is adjacent to the fourth opening in the second direction, and
wherein the projection portion is disposed in a portion of the beam portion between the first and fourth openings.

7. The vapor deposition mask according to claim 1, wherein in the planar view, the beam portion has a grid shape in the recessed portion.

8. The vapor deposition mask according to claim 7,
wherein a plurality of projection portions is present on the upper surface of the beam portion, and
wherein each of the projection portion and the plurality of projection portions is disposed in any of intersection portions of the grid shape.

9. The vapor deposition mask according to claim 1, wherein a bottom portion and an upper portion of the peripheral portion have materials different from each other.

10. The vapor deposition mask according to claim 1, wherein an end of the projection portion and a portion of the peripheral portion including the opposing surface have a same material.

11. A method for manufacturing an organic electroluminescent (EL) element including at least an organic layer between a first electrode and a second electrode, the method comprising:
opposing a vapor deposition mask and a substrate to each other, the vapor deposition mask comprising:
a mask substrate including a recessed portion disposed on an opposing surface opposed to a substrate, and a peripheral portion surrounding the recessed portion; and
a projection portion disposed in the mask substrate,
wherein a bottom portion of the recessed portion includes a first opening and a second opening adjacent to each other in a first direction, a third opening and a fourth opening adjacent to each other in the first direction and adjacent to the first and second openings in a second direction intersecting the first direction, and a beam portion disposed between the first and second openings, between the third and fourth openings, between the first and third openings, between the second and fourth openings, and between the first and fourth openings,
wherein the projection portion is disposed on an upper surface of the beam portion, and
wherein in a case where in a planar view of the upper surface, a region obtained by combining the first to fourth openings and the beam portion is a first region, and a region having a same area and a same outer shape as an area and an outer shape of the first region in the peripheral portion is a second region,
an area of contact of the opposing surface of the second region with a parallel surface parallel to the opposing surface is greater than an area of contact of the opposing surface of the first region with the parallel surface;
adjusting positions of the substrate and the vapor deposition mask;
bringing the substrate and the vapor deposition mask into contact with each other; and
forming a vapor deposition pattern by vapor-depositing a vapor deposition material on the substrate through an opening of the vapor deposition mask,
wherein the substrate or the vapor deposition mask is disposed so that the projection portion and a part of the opposing surface of the peripheral portion are in contact with the substrate in bringing the substrate and the vapor deposition mask into contact with each other.

12. A vapor deposition mask comprising:
a mask substrate including a recessed portion disposed on an opposing surface opposed to a substrate, and a peripheral portion surrounding the recessed portion; and
a plurality of projection portions disposed in the mask substrate,
wherein a bottom portion of the recessed portion includes a plurality of openings and a beam portion disposed between the plurality of openings,
wherein the plurality of projection portions is disposed on an upper surface of the beam portion, and
wherein a projection portion is not disposed on the opposing surface of the peripheral portion.

13. The vapor deposition mask according to claim 12, wherein ends of the plurality of projection portions and a portion of the peripheral portion including the opposing surface have materials different from each other.

14. The vapor deposition mask according to claim 12, wherein ends of the plurality of projection portions have a resin, and the opposing surface of the peripheral portion has a metal.

15. The vapor deposition mask according to claim 12, wherein in a cross section passing through at least one of the plurality of projection portions and the beam portion, a distance from an upper surface of the bottom portion of the recessed portion to an upper surface of the at least one projection portion in a direction perpendicular to the opposing surface is greater than a distance from the upper surface of the bottom portion to an upper surface of the peripheral portion in the direction perpendicular to the opposing surface.

16. The vapor deposition mask according to claim 12,
wherein the plurality of openings includes a first opening and a second opening adjacent to each other in a first direction, and a third opening and a fourth opening adjacent to each other in the first direction,
wherein the second opening is adjacent to the fourth opening in a second direction intersecting the first direction,
wherein the second opening is adjacent to the fourth opening in the second direction, and
wherein one of the plurality of projection portions is disposed in a portion of the beam portion between the first and fourth openings.

17. The vapor deposition mask according to claim 12, wherein in a planar view of the upper surface, the beam portion has a grid shape in the recessed portion.

18. The vapor deposition mask according to claim 17, wherein each of the plurality of projection portions is disposed in any of intersection portions of the grid shape.

19. The vapor deposition mask according to claim 11, wherein a bottom portion and an upper portion of the peripheral portion have materials different from each other.

20. The vapor deposition mask according to claim 12, wherein ends of the plurality of projection portions and a portion of the peripheral portion including the opposing surface have a same material.

21. A method for manufacturing an organic electroluminescent (EL) element including at least an organic layer between a first electrode and a second electrode, the method comprising:
opposing a vapor deposition mask and a substrate to each other, the vapor deposition mask comprising:
a mask substrate including a recessed portion disposed on an opposing surface opposed to a substrate, and a peripheral portion surrounding the recessed portion; and
a plurality of projection portions disposed in the mask substrate,
wherein a bottom portion of the recessed portion includes a plurality of openings and a beam portion disposed between the plurality of openings,
wherein the plurality of projection portions is disposed on an upper surface of the beam portion, and
wherein a projection portion is not disposed on the opposing surface of the peripheral portion;
adjusting positions of the substrate and the vapor deposition mask;
bringing the substrate and the vapor deposition mask into contact with each other; and
forming a vapor deposition pattern by vapor-depositing a vapor deposition material on the substrate through an opening of the vapor deposition mask,
wherein the substrate or the vapor deposition mask is disposed so that the projection portion and a part of the opposing surface of the peripheral portion are in contact with the substrate in bringing the substrate and the vapor deposition mask into contact with each other.
